(19) United States
(12) Patent Application Publication
(10) Pub. No.: US 2013/0220783 A1
(43) Pub. Date: Aug. 29, 2013

(54) MEMS Switch Having One or More Vacuum Gaps

(71) Applicants: Ilkka Urvas, Espoo (FI); Andrei Pavlov, Naantali (FI); Yelena Pavlova, Naantali (FI)

(72) Inventors: Ilkka Urvas, Espoo (FI); Andrei Pavlov, Naantali (FI); Yelena Pavlova, Naantali (FI)

(21) Appl. No.: 13/396,539

(22) Filed: Feb. 14, 2012

Related U.S. Application Data
(60) Provisional application No. 61/442,367, filed on Feb. 14, 2011.

(51) Int. Cl. B81B 3/00

(52) U.S. Cl. CPC B81B 3/0086
USPC 200/181

(57) ABSTRACT

A MEMS switch comprises a top conductor and at least one first insulator layer having a lateral opening. The at least one first insulator layer hermetically seals the top conductor. At least one second insulator layer is positioned below the at least one first insulator layer such that at least one vacuum gap is formed within the lateral opening between the top conductor and the at least one second insulator layer. The at least one vacuum gap has a thickness in the range 0.5 Å to 100 Å when the top conductor is at rest. The thickness of the at least one vacuum gap varies when the top conductor is moved. The insulator layer has at least one opening that exposes a conducting area of at least one contact conductor within the second insulator layer. At least one actuation conductor that is electrically insulated from the at least one contact conductor such that application of at least one actuation voltage to the at least one actuation conductor moves the at least one contact conductor and the top conductor closer to each other within the at least one vacuum gap.

### CROSS-REFERENCE TO RELATED APPLICATIONS

This patent application claims the benefit of U.S. Provisional Application Ser. No. 61/442,367, filed Feb. 14, 2011, the contents of which are hereby incorporated by reference herein.

### BACKGROUND OF THE INVENTION

The present invention is in the technical field of integrated thin film devices. More particularly, the present invention is in the technical field of microelectromechanical devices.

Conventional electronic devices, such as switches, variable capacitors, resonators, sensors and digital logic circuits have a limited performance and/or complicated manufacturing process with the existing technologies. In semiconductor devices the device performance is often limited by the non-ideal properties of the semiconductor transistors and diodes when the device is used as a switch, as the semiconducting material has a limited isolation and experiences some leakage of the signal during the switching operation. This degrades the electrical performance of the circuit and increase the power consumption, which is especially critical in the battery powered applications. On the other hand the conventional microelectromechanical devices typically have more complicated and costly processing steps compared to semiconductor devices and require expensive packaging.

### SUMMARY OF THE INVENTION

Briefly according to the present invention, a MEMS switch comprises a top conductor and at least one first insulator layer having a lateral opening. The at least one first insulator layer hermetically seals the top conductor. At least one second insulator layer is positioned below the at least one first insulator layer such that at least one vacuum gap is formed within the lateral opening between the top conductor and the at least one second insulator layer. The at least one vacuum gap has a thickness in the range 0.5 Å to 100 Å when the top conductor is at rest. The thickness of the at least one vacuum gap varies when the top conductor is moved. The insulator layer has at least one opening that exposes a conducting area of at least one contact conductor within the second insulator layer. At least one actuation conductor that is electrically insulated from the at least one contact conductor such that application of at least one actuation voltage to the at least one actuation conductor moves the at least one contact conductor and the top conductor closer to each other within the at least one vacuum gap.

According to some of the more detailed features of the present invention, the at least one contact conductor is positioned within the at least one opening of the second insulator layer such that upon application of the actuation voltage a mechanical contact is created between the top conductor and the at least one contact conductor. The at least one contact conductor is positioned within the at least one opening of the second insulator layer such that upon application of the actuation voltage to the at least one actuation conductor a high conduction path is created between the top conductor and the at least one contact conductor without forming a mechanical contact between them. The top conductor and the at least one actuation conductor are spaced to minimize parasitic capacitance.

According to still more detailed features of the present invention, a bottom interconnection is in electrical contact with the contact conductor. The bottom interconnection is disposed below the at least one second insulation layer. At least one of the first insulator layer or the at least one second insulator layer comprise at least one of silicon oxide, silicon nitride or low-k material. At least one third insulator layer insulates the bottom conductor from a carrier of MEMS device. The carrier material comprises at least one of silicon, gallium arsenide, glass, quartz or sapphire. The top conductor comprises at least one of gold, tungsten, copper, aluminum or polysilicon.

According to yet other more detailed features of the present invention, the at least one contact conductor comprises a plurality of contact conductors, wherein the second insulator layer has a plurality of openings each exposing a conducting area of a corresponding one of the plurality of the contact conductors to increase actuation area. The at least one actuation conductor comprises a plurality of actuation conductors for applying different actuation voltages to each one of the plurality of actuation conductors.

According to still yet other more detailed features of the present invention the at least one contact conductor is positioned within the at least one opening of the at least one second insulator layer such that a high conduction path is creating between the top conductor and the at least one contact conductor without forming a mechanical contact there between.

According to other more detailed features of the present invention, at least one middle conductor is positioned between the top conductor and the at least one first insulator layer thereby forming a plurality of vacuum gaps, each one of the plurality of vacuum gaps having a thickness in the range 0.5 Å to 100 Å.

### BRIEF DESCRIPTION OF THE DRAWINGS

FIG. 1 is a cross-section view of a single vacuum gap device with top conductor, vacuum gap and bottom conductor;

FIG. 2 is a top view of a single vacuum gap device with top conductor, vacuum gap and bottom conductor;

FIG. 3 is a cross-section view of a single vacuum gap device with top conductor, vacuum gap, bottom conductor and insulator layer;

FIG. 4 is a cross-section view of a single vacuum gap device with device with top conductor, vacuum gap, bottom conductor and residual insulator layer at the top of the vacuum gap;

FIG. 5 is a cross-section view of a single vacuum gap device with device with top conductor, vacuum gap, bottom conductor and residual insulator layer at the bottom of the vacuum gap;

FIG. 6 is a cross-section view of a single vacuum gap device that can be used as switch with top conductor, vacuum gap, contact conductor, actuation conductor, insulator layer and bottom conductor;

FIG. 7 is a top view of a single vacuum gap device that can be used as switch with top conductor, vacuum gap, contact conductor, actuation conductor, insulator layer and bottom conductor;

FIG. 8 is a cross section view of high frequency version of a single vacuum gap device that can be used as switch with top conductor, actuation conductor, vacuum gap, contact conductor, insulator layer and bottom conductor;

FIG. 9 is a top view of high frequency version of a single vacuum gap device that can be used as switch with top conductor, vacuum gap, contact conductor, actuation conductor, insulator layer and bottom conductor;

FIG. 10 is a cross section view of high frequency version of a single vacuum gap device that can be used as switch with top conductor, actuation conductor, vacuum gap, multiple contact conductors, insulator layer and bottom conductor;

FIG. 11 is a top view of high frequency version of a single vacuum gap device that can be used as switch with top conductor, vacuum gap, contact conductor, actuation conductor, multiple contact conductors, insulator layer and bottom conductor;

FIG. 12 is a cross section view of high frequency version of a single vacuum gap device that can be used as switch with top conductor, multiple actuation conductors, vacuum gap, multiple contact conductors, insulator layer and bottom conductor;

FIG. 13 is a top view of high frequency version of a single vacuum gap device that can be used as switch with top conductor, vacuum gap, contact conductor, multiple actuation conductors, multiple contact conductors, insulator layer and bottom conductor;

FIG. 14 is a close-up of the center area of FIG. 13;

FIG. 15 is a cross section view of high frequency version of a dual vacuum gap device that can be used as switch with top conductor, actuation conductor, vacuum gap, multiple contact conductors, insulator layer and bottom conductor;

FIG. 16 is a cross section view of high frequency version of a single vacuum gap device that can be used as switch with top conductor, vacuum gap, contact conductor, insulator layer and bottom conductor;

FIG. 17 is a top view of different contact conductor configurations for a vacuum gap device that can be used as switch;

FIG. 18 is a cross section view of a vacuum gap device with reinforced top conductor;

FIG. 19 is a top view of a vacuum gap device with reinforced top conductor having same shape as the vacuum gap;

FIG. 20 is a top view of a vacuum gap device with reinforced top conductor having a plus shape;

FIG. 21 is a top view of a vacuum gap device with reinforced top conductor having a cantilever shape;

FIG. 22 is a cross-section view of a double vacuum gap device with two conducting plates;

FIG. 23 is a top view of a double vacuum gap device with two conducting plates;

FIG. 24 is a cross-section view of a double vacuum gap device with three conducting layers;

FIG. 25 is a top view of the bottom conductor layer within a double vacuum gap device with three conducting layers.

FIG. 26 is a cross-section view of a double vacuum gap device with three conducting layers where the top and bottom layers have both contact and insulated areas;

FIG. 27 is a top view of the top conductor layer within a double vacuum gap device with three conducting layers where the top and bottom layers have both contact and insulated areas;

FIG. 28 is a top view of the bottom conductor layer within a double vacuum gap device with three conducting layers where the top and bottom layers have both contact and insulated areas;

FIG. 29 is a cross-section view of a single gap cantilever device with vertical actuation;

FIG. 30 is a top view of a single gap cantilever device with vertical actuation;

FIG. 31 is a cross-section view of a single gap cantilever device with lateral actuation;

FIG. 32 is a top view of a single gap cantilever device with lateral actuation;

FIG. 33 is a cross-section view of a single vacuum gap static capacitor;

FIG. 34 is a top view of a single vacuum gap static capacitor;

FIG. 35 is a symbol of a MEMS switch;

FIG. 36 is a digital inverter circuit made with MEMS switches;

FIG. 37 is a NAND gate made with MEMS switches;

FIG. 38 is a NOR gate made with MEMS switches AND;

FIG. 39 is a perspective view showing only the conductors of a single vacuum gap device 140 with an additional interconnection connected to the top conductor.

FIGS. 40 to 57 show fabrication steps of a dual gap MEMS switch.

FIG. 58 is a MEMS switch with electron cloud contact (ECC).

### DETAILED DESCRIPTION OF THE INVENTION

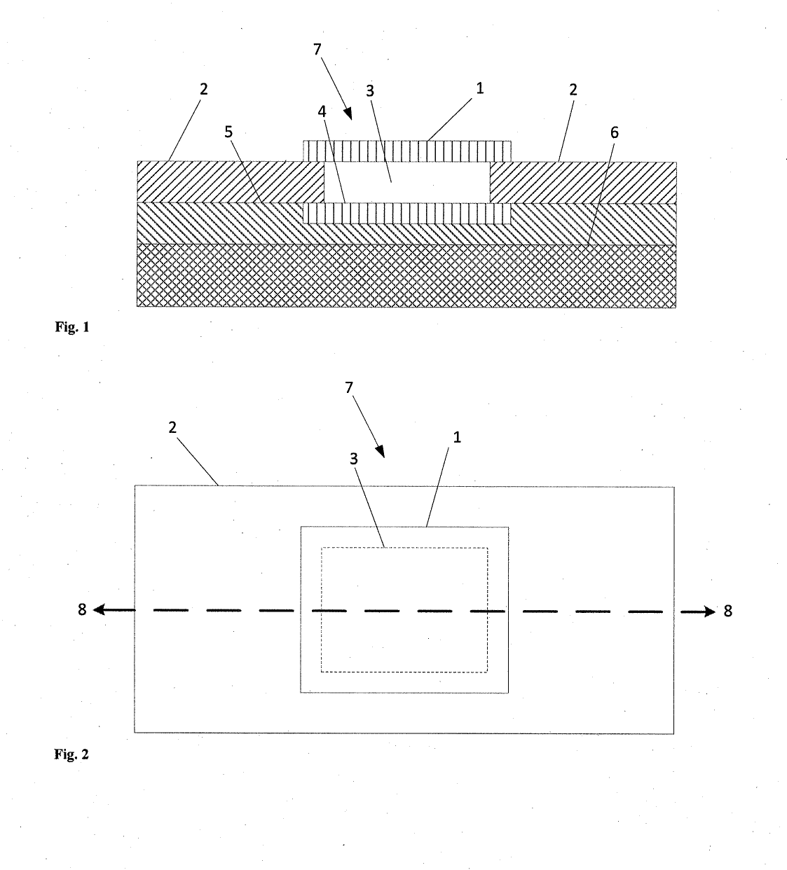

Referring now to the invention in more detail, in FIG. 1 and FIG. 2 there is shown a single vacuum gap device 7 having a top conductor 1 that is on the top of an insulator layer 2 and a vacuum gap 3. The top conductor 1 is covering the vacuum gap 3 area so that it is hermetically sealed. The bottom of the vacuum gap 3 is limited by a bottom conductor 4 and/or another insulator layer 5. The single vacuum gap device 7 is above carrier material 6. The location of cross-sectioning for FIG. 1 is shown by the dashed line 8 in FIG. 2.

In more detail, still referring to the invention of FIG. 1 and FIG. 2 the top conductor 1, the vacuum gap 3 and the bottom conductor 4 form an electrical device that can be a quantum tunneling device or a capacitor depending on the distance between the top conductor 1 and bottom conductor 4 i.e. the thickness of the vacuum gap 3. The thickness of the vacuum gap 3 can vary as a function of an external pressure that is applied on the top conductor 1 or as a function of electrostatic force. The electrostatic force can be generated for example by applying an actuation voltage between the top conductor 1 and bottom conductor 4. The forces will attract the top conductor 1 and the bottom conductor 4 closer to each other. As a result the electrical properties of the single vacuum gap device 7 will change so that in the case of quantum tunneling the conductivity of the single vacuum gap device 7 will increase as the thickness of the vacuum gap 3 decreases and in the case of capacitive coupling the capacitance of the single vacuum gap device 7 will increase as the thickness of the vacuum gap 3 decreases. The single gap vacuum gap device 7 can be used for example as a sensor to measure the ambient pressure or as an electrically controlled variable capacitor in an electrical circuit.

In further detail, still referring to the invention of FIG. 1 and FIG. 2, the geometry of the vacuum gap 3 may be arbitrary such as for example rectangular, octagonal, elliptical and so forth. Assuming a rectangular shape for the vacuum gap 3 the typical lateral dimensions may vary from 20 nm to 200 um. The typical thickness of the vacuum gap 3 may vary from 0.5 Å to 100 Å for quantum tunneling applications and from 5 nm to 500 nm for capacitive applications. The typical thicknesses of the top conductor 1 and bottom conductor 4 may vary from 5 nm to 10 um.

The manufacturing of the invention of FIG. 1 and FIG. 2 can be done by using conventional thin film processing techniques with compatible materials, for example: silicon, gallium arsenide, glass, quartz or sapphire as the carrier material 6; gold, tungsten, copper, aluminum or polysilicon as the conductor material for the top conductor 1 and the bottom conductor 4; silicon oxide, silicon nitride or low-k dielectric for the insulator layers 2, 5. Low-k dielectric material for example, are MnO, FeO, CaO, NiO, Cr2O3, Fe2O3, Al2O3, Si3N4. The carrier material 6 may be for example a semiconductor substrate, glass, quartz or a layer of a microelectronic circuit containing other devices on and/or below it.

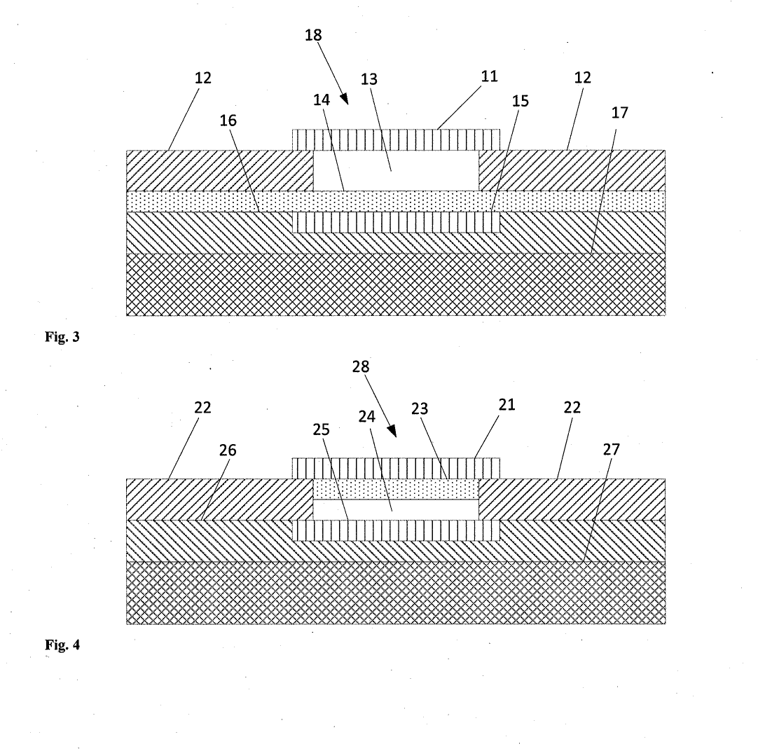

Referring now to the invention shown in FIG. 3 there is shown a single vacuum gap device 18 having a top conductor 11 that is on the top of the insulator layer 12 and the vacuum gap 13. The top conductor 11 is covering the vacuum gap 13 area so that it is hermetically sealed. The bottom of the vacuum gap 13 is limited by the insulator layer 14 which isolates the bottom conductor 15 that is on the insulator layer 16. The single vacuum gap device 18 is above the carrier material 17.

In more detail, still referring to the invention of FIG. 3, a top conductor 11, a vacuum gap 13, an insulator layer 14 and a bottom conductor 15 form an electrical device that can be a quantum tunneling device or a capacitor depending on the distance between the top conductor 11 and bottom conductor 15 i.e. the thickness of the vacuum gap 13 and the insulator layer 14. The thickness of the vacuum gap 13 can vary as a function of an external pressure that is applied on the top conductor 11 or as a function of electrostatic force. The electrostatic force can be generated for example by applying an actuation voltage between the top conductor 11 and bottom conductor 15. The forces will attract the top conductor 11 closer to the bottom conductor 15. As a result the electrical properties of the single vacuum gap device 18 will change so that in the case of quantum tunneling the conductivity of the single vacuum gap device 18 will increase as the thickness of the vacuum gap 13 decreases and in the case of capacitive coupling the capacitance of the single vacuum gap device 18 will increase as the thickness of the vacuum gap 13 decreases. The insulator layer 14 will prevent an electrical contact between the top conductor 11 and the bottom conductor 15, so it is possible to pull down the top conductor 11 without causing a short circuit. The single conductor gap vacuum gap device 18 can be used for example as a sensor to measure the ambient pressure or as an electrically controlled variable capacitor in an electrical circuit. It is possible to use the single gap vacuum gap device 18 in two-state mode so that in the first state there are no forces applied to the top conductor 11, and in the second state there is a force applied to the top conductor 11 so that it is moved down against the insulator layer 14. An example of such device would be a digital capacitor with a lower capacitance value when actuation voltage would be 0 V and a higher capacitance value when the actuation voltage is such that it will pull down and hold the top conductor 11.

In further detail, still referring to the invention of FIG. 3, the lateral geometry of the vacuum gap 13 may be arbitrary such as for example rectangular, octagonal, elliptical and so forth. Assuming a rectangular shape for the vacuum gap 13 the typical lateral dimensions may vary from 20 nm to 200 um. The typical thickness of the vacuum gap 13 may vary from 0.5 Å to 100 Å for quantum tunneling applications and from 5 nm to 500 nm for capacitive applications. The typical thicknesses of the top conductor 11 and bottom conductor 15 may vary from 5 nm to 10 um. The typical thickness of the insulator layer 14 may vary from 1 Å to 100 Å for quantum tunneling applications and from 5 nm to 500 nm for capacitive applications.

The manufacturing of the invention of FIG. 3 can be done by using conventional thin film processing techniques with compatible materials, for example: silicon, gallium arsenide, glass, quartz or sapphire as the carrier material 17; gold, tungsten, copper, aluminum or polysilicon as the conductor material for the top conductor 11 and the bottom conductor 15; silicon oxide, silicon nitride, low-k dielectric or tantalum oxide for the insulator layers 12, 14 and 16. The carrier material 17 may be for example a semiconductor substrate, glass, quartz or a layer of a microelectronic circuit containing other devices on and/or below it Referring now to the invention shown in FIG. 4 there is shown a single vacuum gap device 28 having a top conductor 21 that is on the top of an insulator layer 22 and a residual insulator layer 23. The top conductor 21 and the residual insulator layer 23 are covering a vacuum gap 24 area so that it is hermetically sealed. The bottom of the vacuum gap 24 is limited by a bottom conductor 25 and/or an insulator layer 26. The single vacuum gap device 28 is above the carrier material 27.

In more detail, still referring to the invention of FIG. 4, the top conductor 21, the residual insulator layer 23, the vacuum gap 24 and the bottom conductor 25 form an electrical device that can be a quantum tunneling device or a capacitor depending on the distance between the top conductor 21 and bottom conductor 25 i.e. the thickness of the residual insulator layer 23 and the vacuum gap 24. The thickness of the vacuum gap 24 can vary as a function of an external pressure that is applied on the top conductor 21 or as a function of electrostatic force. The electrostatic force can be generated for example by applying an actuation voltage between the top conductor 21 and bottom conductor 25. The forces will attract the top conductor 21 closer to the bottom conductor 25. As a result the electrical properties of the single vacuum gap device 28 will change so that in the case of quantum tunneling the conductivity of the single vacuum gap device 28 will increase as the thickness of the vacuum gap 24 decreases and in the case of capacitive coupling the capacitance of the single vacuum gap device 28 will increase as the thickness of the vacuum gap 24 decreases. The residual insulator layer 23 will prevent an electrical contact between the top conductor 21 and the bottom conductor 25, so it is possible to pull down the top conductor 21 without causing a short circuit. The single gap vacuum gap device 28 can be used for example as a sensor to measure the ambient pressure or as an electrically controlled variable capacitor in an electrical circuit. It is possible to use the single gap vacuum gap device 28 in two-state mode so that in the first state there are no forces applied to the top conductor 21, and in the second state there is a force applied to the top conductor 21 so that it is moved down against the insulator layer 23. An example of such device would be a digital capacitor with a lower capacitance value when actuation voltage would be 0 V and a higher capacitance value when the actuation voltage is such that it will pull down and hold the top conductor 21.

In further detail, still referring to the invention of FIG. 4, the lateral geometry of the vacuum gap 24 may be arbitrary such as for example rectangular, octagonal, elliptical and so forth. Assuming a rectangular shape for the vacuum gap 24 the typical lateral dimensions may vary from 20 nm to 200 um. The typical thickness of the vacuum gap 24 may vary from 0.5 Å to 100 Å for quantum tunneling applications and from 5 nm to 500 nm for capacitive applications. The typical thicknesses of the top conductor 21 and bottom conductor 25 may vary from 5 nm to 10 um. The typical thickness of the insulator layer 23 may vary from 1 Å to 100 Å for quantum tunneling applications and from 5 nm to 500 nm for capacitive applications.

The manufacturing of the invention of FIG. 4 can be done by using conventional thin film processing techniques with compatible materials, for example: silicon, gallium arsenide, glass, quartz or sapphire as the carrier material 27; gold, tungsten, copper, aluminum or polysilicon as the conductor material for the top conductor 21 and the bottom conductor 25; silicon oxide, silicon nitride, low-k dielectric or tantalum oxide for the insulator layers 22 and 26. The residual insulator layer 23 is formed in the creation of the vacuum gap 24 and may be for example Al2O3 or CuO depending on the used materials. The carrier material 27 may be for example a semiconductor substrate, glass, quartz or a layer of a microelectronic circuit containing other devices on and/or below it.

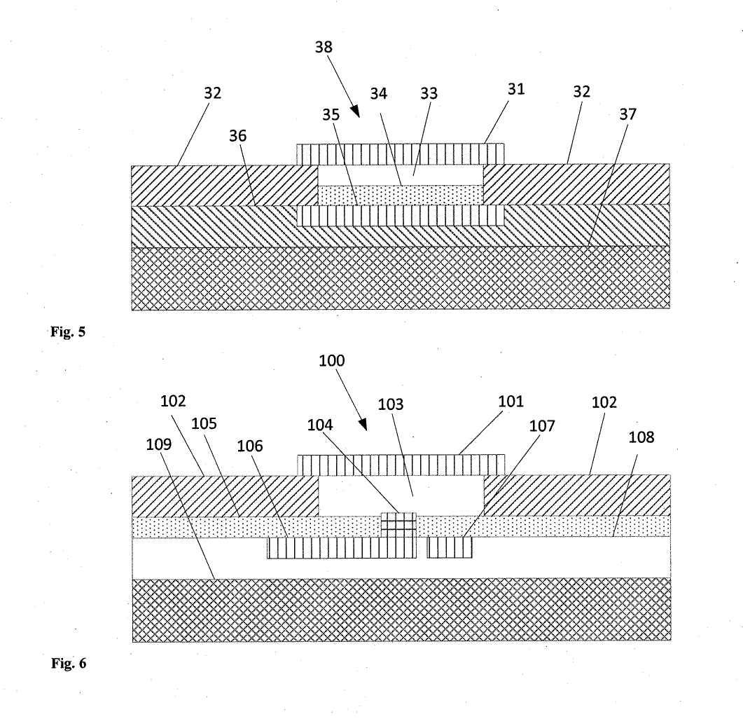

Referring now to the invention shown in FIG. 5 there is shown a single vacuum gap device 38 having a top conductor 31 that is on the top of an insulator layer 32 and a vacuum gap 33. The top conductor 31 is covering the vacuum gap 33 area so that it is hermetically sealed. The bottom of the vacuum gap 33 is limited by a residual insulator layer 34. The bottom conductor 35 is below the residual insulator layer 34 and on top of the insulator layer 36. The single vacuum gap device 38 is above the carrier material 37.

In more detail, still referring to the invention of FIG. 5, the top conductor 31, the residual insulator layer 34, the vacuum gap 33 and the bottom conductor 35 form an electrical device that can be a quantum tunneling device or a capacitor depending on the distance between the top conductor 31 and bottom conductor 35 i.e. the thickness of the residual insulator layer 34 and the vacuum gap 33. The thickness of the vacuum gap 33 can vary as a function of an external pressure that is applied on the top conductor 31 or as a function of electrostatic force. The electrostatic force can be generated for example by applying an actuation voltage between the top conductor 31 and bottom conductor 35. The forces will attract the top conductor 31 closer to the bottom conductor 35. As a result the electrical properties of the single vacuum gap device 38 will change so that in the case of quantum tunneling the conductivity of the single vacuum gap device 38 will increase as the thickness of the vacuum gap 33 decreases and in the case of capacitive coupling the capacitance of the single vacuum gap device 38 will increase as the thickness of the vacuum gap 33 decreases. The residual insulator layer 34 will prevent an electrical contact between the top conductor 31 and the bottom conductor 35, so it is possible to pull down the top conductor 31 without causing a short circuit. The single gap vacuum gap device 38 can be used for example as a sensor to measure the ambient pressure or as an electrically controlled variable capacitor in an electrical circuit. It is possible to use the single gap vacuum gap device 38 in two-state mode so that in the first state there are no forces applied to the top conductor 31, and in the second state there is a force applied to the top conductor 31 so that it is moved down against the insulator layer 34. An example of such device would be a digital capacitor with a lower capacitance value when actuation voltage would be 0 V and a higher capacitance value when the actuation voltage is such that it will pull down and hold the top conductor 31.

In further detail, still referring to the invention of FIG. 5, the lateral geometry of the vacuum gap 33 may be arbitrary such as for example rectangular, octagonal, elliptical and so forth. Assuming a rectangular shape for the vacuum gap 33 the typical lateral dimensions may vary from 20 nm to 200 um. The typical thickness of the vacuum gap 33 may vary from 0.5 Å to 100 Å for quantum tunneling applications and from 5 nm to 500 nm for capacitive applications. The typical thicknesses of the top conductor 31 and bottom conductor 35 may vary from 5 nm to 10 um. The typical thickness of the insulator layer 34 may vary from 1 Å to 100 Å for quantum tunneling applications and from 5 nm to 500 nm for capacitive applications.

The manufacturing of the invention of FIG. 5 can be done by using conventional thin film processing techniques with compatible materials, for example: silicon, gallium arsenide, glass, quartz or sapphire as the carrier material 37; gold, tungsten, copper, aluminum or polysilicon as the conductor material for the top conductor 31 and the bottom conductor 35; silicon oxide, silicon nitride, low-k dielectric or tantalum oxide for the insulator layers 32 and 36. The residual insulator layer 34 is formed in the creation of the vacuum gap 33 and may be for example Al2O3 or CuO depending on the used materials. The carrier material 37 may be for example a semiconductor substrate, glass, quartz or a layer of a microelectronic circuit containing other devices on and/or below it.

The single gap vacuum gap devices 7, 18, 28 and 38 of FIG. 1-FIG. 5 can be used as a sensor in resonance mode so that the device is excited with an AC electrical signal to resonate in one of its natural mechanical resonance frequencies. The sensing measurement can be based on any physical phenomenon or phenomena that affect the mechanical resonance frequency, mechanical quality factor and/or amplitude of the mechanical displacement, such as device temperature, ambient pressure, actuation voltage, charging of device materials, acoustic waves, electromagnetic radiation, gravitational fields, acceleration forces and so forth. Additional areas on an integrated circuit with the vacuum gap devices 7, 18, 28 and 38 can be used, e.g., for charge accumulation so that they are interconnected electrically to the single gap vacuum gap device for sensing.

All single gap vacuum gap based devices referenced in this application can be used as a variable capacitor or detector, where the lateral size and shape of the bottom conductor or conductors may vary freely. There may be more than one electrically separate bottom conductors so that at least one of the bottom conductors is used as an actuation electrode and at least one of the bottom conductors acts as a plate forming a capacitor, resonator or quantum tunneling device together with the top conductor.

Still referring to all single vacuum gap based devices of this document that can be used as a variable capacitor or detector, the device may be used as a thermionic or thermotunneling diode.

### The Switch

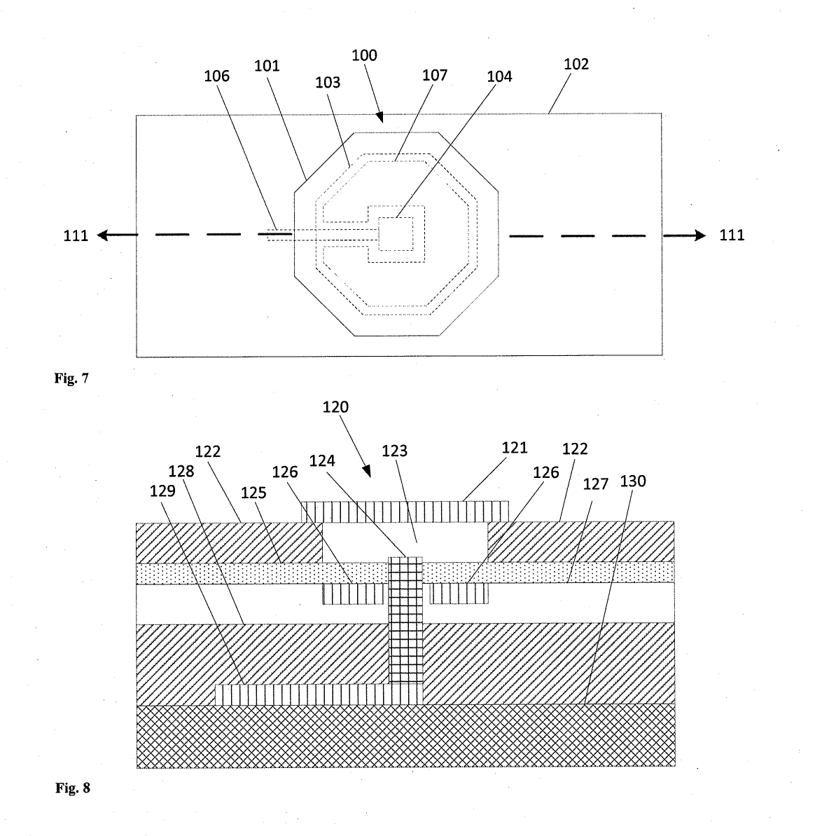

Referring now to the invention shown in FIG. 6 and FIG. 7 there is shown a single vacuum gap device 100 having a top conductor 101 that is on the top of an insulator layer 102 and a vacuum gap 103. The top conductor 101 is covering the vacuum gap 103 area so that it is hermetically sealed. The bottom of the vacuum gap 103 is limited by another insulator layer 105 and a contact conductor 104, which exposes a conducting area within the insulator layer 105. The bottom interconnection 106 and actuation conductor 107 are below the insulator layer 105 and on top of the insulator layer 108. The single vacuum gap device 100 is on top of the carrier material 109. The location of cross-sectioning for FIG. 6 is shown by the dashed line 111 in FIG. 7.

In more detail, still referring to the invention of FIG. 6 and FIG. 7, the top conductor 101, the insulator layer 105, the vacuum gap 103, the contact conductor 104 and the actuation conductor 107 form a mechanical switch. The top conductor 101 can be actuated by electrostatic force so that it is moved down against the contact conductor 104 forming an ohmic contact. The electrostatic force can be generated for example by applying an actuation voltage between the top conductor 101 and the actuation conductor 107. The insulator layer 105 will prevent an electrical contact between the top conductor 101 and the actuation conductor 107, so it is possible to pull down the top conductor 101 without causing a short circuit. The switch is in open state when actuation voltage between the top conductor 101 and actuation conductor 107 is low (ideally 0 V), and in closed state when the actuation voltage is sufficient to pull down and hold the top conductor 101 against the contact conductor 104, which is positioning to have a conducting surface exposed within the insulator layer 105. The exposed conduct area may be flash with above or slightly below the top surface of the insulator layer 105, to provide electrical connection between conductors 104 and 105. The Exposed conducting area may be flash with above, or slightly below the top surface of the insulator layer 105 to provide electrical connection between conductors 104 and 101.

In further detail, still referring to the invention of FIG. 6 and FIG. 7, the lateral geometry of the vacuum gap 103 may be arbitrary such as for example rectangular, octagonal, elliptical and so forth. Assuming an octagonal shape for the vacuum gap 103, such as shown in FIG. 7, the typical dimensions may vary from 20 nm to 200 um. The typical thickness of the vacuum gap 103 may vary from 1 nm to 500 nm. The typical thicknesses of the top conductor 101, contact conductor 104 and the actuation conductor 107 may vary from 50 nm to 10 um. The typical thickness of the insulator layer 105 may vary from 1 nm to 500 nm. The lateral size and shape of the actuation electrode 107 may vary as discussed separately, however the size is typically equivalent or smaller than that of the vacuum gap 103. An opening in the actuation conductor 107 is left so that the bottom interconnection 106 has access to the contact conductor 104.

The manufacturing of the invention of can be done by using conventional thin film processing techniques with compatible materials, for example: silicon, gallium arsenide, glass, quartz or sapphire as the carrier material 109; gold, tungsten, copper, aluminum or polysilicon as the conductor material for the top conductor 101, contact conductor 104, bottom interconnection 106, and the actuation conductor 107; silicon oxide, silicon nitride, tantalum nitride, or low-k dielectric for the insulator layers 102, 105 and 108. The carrier material 109 may contain several layers of a microelectronic circuit containing other devices on and/or below it.

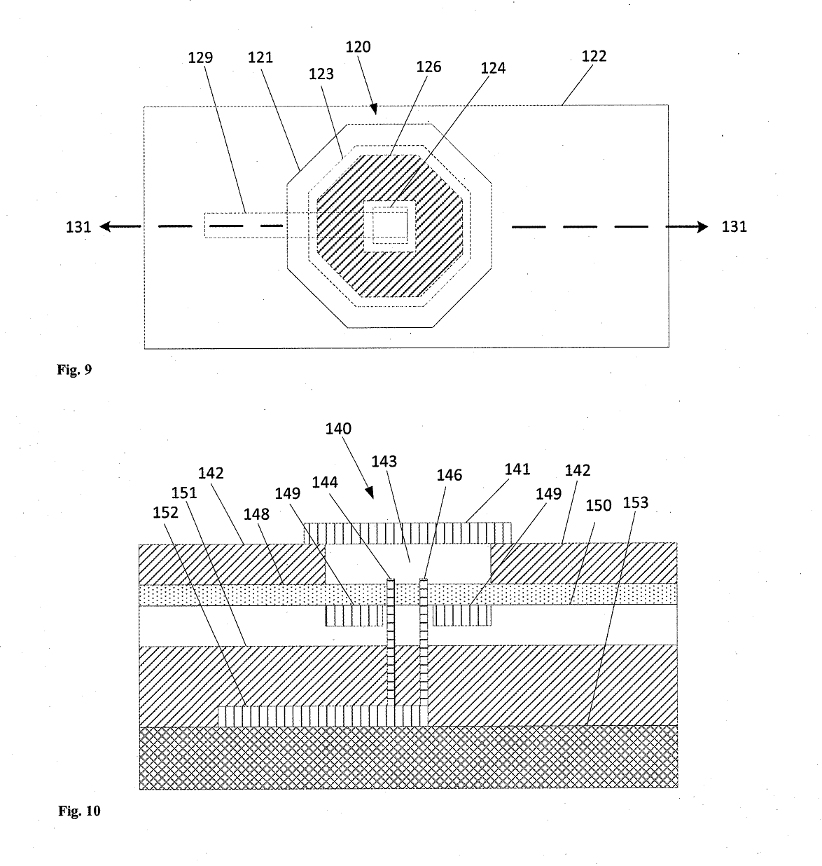

Referring now to the invention shown in FIG. 8 and FIG. 9 there is shown a single vacuum gap device 120 having a top conductor 121 that is on the top of an insulator layer 122 and a vacuum gap 123. The top conductor 121 is covering the vacuum gap 123 area so that it is hermetically sealed. The bottom of the vacuum gap 123 is limited by an insulator layer 125 and a contact conductor 124. An actuation conductor 126 is below the insulator layer 125 and on top of an insulator layer 127. The bottom interconnection 129 and single vacuum gap device 120 are on top of a carrier material 130. An insulator layer 128 provides physical separation between a bottom interconnection 129 and the other conductors and may consist of several separate insulator layers. The location of cross-sectioning for is shown by the dashed line 131 in FIG. 9.

In more detail, still referring to the invention of FIG. 8 and FIG. 9, the top conductor 121, the insulator layer 125, the vacuum gap 123, the contact conductor 124 and the actuation conductor 126 form a mechanical switch. The top conductor 121 can be actuated by electrostatic force so that it is moved down against the contact conductor 124 forming an ohmic contact in the manner described in connection with FIGS. 6 and 7. The electrostatic force can be generated for example by applying an actuation voltage between the top conductor 121 and the actuation conductor 126. The insulator layer 125 will prevent an electrical contact between the top conductor 121 and the actuation conductor 126, so it is possible to pull down the top conductor 121 without causing a short circuit. The switch is in open state when actuation voltage between the top conductor 121 and actuation conductor 126 is low (ideally 0 V), and in closed state when the actuation voltage is such that it will pull down and hold the top conductor 121.

In further detail, still referring to the invention of FIG. 8 and FIG. 9, the lateral geometry of the vacuum gap 123 may be arbitrary such as for example rectangular, octagonal, elliptical and so forth. Assuming an octagonal shape for the vacuum gap 123, such as shown in FIG. 9, the typical dimensions may vary from 20 nm to 200 um. The typical thickness of the vacuum gap 123 may vary from 1 nm to 500 nm. The typical thicknesses of the top conductor 121, contact conductor 124 and the actuation conductor 126 may vary from 50 nm to 10 um. The typical thickness of the insulator layer 125 may vary from 1 nm to 500 nm. The lateral size and shape of the actuation electrode 126 may vary as discussed separately, however the size is typically equivalent or smaller than that of the vacuum gap 123. An opening in the actuation conductor 126 is left so that the contact conductor 124 has access to the bottom interconnection 129.

The manufacturing of the invention of can be done by using conventional thin film processing techniques with compatible materials, for example: silicon, gallium arsenide, glass, quartz or sapphire as the carrier material 130; gold, tungsten, copper, aluminum or polysilicon as the conductor material for the top conductor 121, contact conductor 124, bottom interconnection 129, and the actuation conductor 126; silicon oxide, silicon nitride, tantalum nitride, or low-k dielectric for the insulator layers 122, 125, 127 and 128. The carrier material 130 may contain several layers of a microelectronic circuit containing other devices on and/or below it.

Comparing single vacuum gap device 100 and single vacuum gap device 120, the latter is better suitable for high frequency applications where the parasitic capacitance between the bottom interconnection 129, and the top conductor 121 and the actuation conductor 126 is reduced due to their increased spacing.

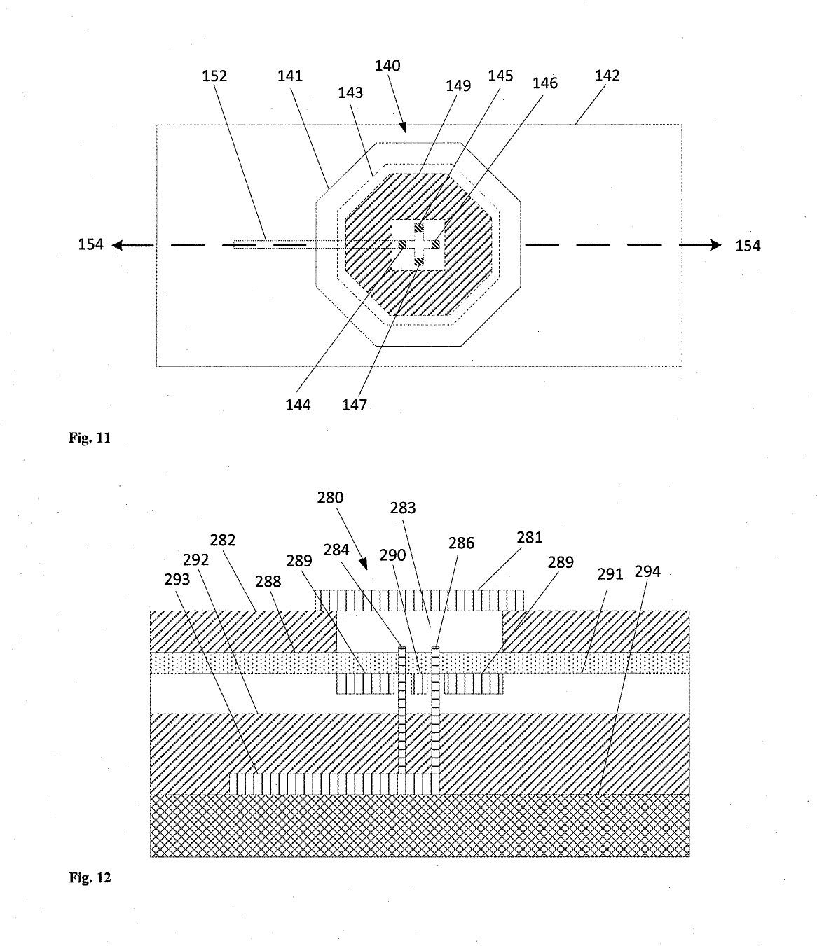

Referring now to the invention shown in FIG. 10 and FIG. 11 there is shown a single vacuum gap device 140 having a top conductor 141 that is on the top of an insulator layer 142 and the vacuum gap 143. The top conductor 141 is covering the vacuum gap 143 area so that it is hermetically sealed. The bottom of the vacuum gap 143 is limited by an insulator layer 148 and contact conductors 144, 145, 146 and 147. An actuation conductor 149 is below the insulator layer 148 and on top of the insulator layer 150. A bottom interconnection 152 and single vacuum gap device 140 are on top of a carrier material 153. The insulator layer 151 provides physical separation between the bottom interconnection 152 and the other conductors and may consist of several separate insulator layers. The location of cross-sectioning for FIG. 10 is shown by the dashed line 154 in FIG. 11.

In more detail, still referring to the invention of FIG. 10 and FIG. 11, the top conductor 141, the insulator layer 148, the vacuum gap 143, the contact conductors 144, 145, 146 and 147, and the actuation conductor 149 form a mechanical switch. The top conductor 141 can be actuated by electrostatic force so that it is moved down against the contact conductors 144, 145, 146 and 147 forming an ohmic contact. The electrostatic force can be generated for example by applying an actuation voltage between the top conductor 141 and the actuation conductor 149. The insulator layer 148 will prevent an electrical contact between the top conductor 141 and the actuation conductor 149, so it is possible to pull down the top conductor 141 without causing a short circuit. The switch is in open state when actuation voltage between the top conductor 141 and actuation conductor 149 is low (ideally 0 V), and in closed state when the actuation voltage is such that it will pull down and hold the top conductor 141.

In further detail, still referring to the invention of FIG. 10 and FIG. 11, the lateral geometry of the vacuum gap 143 may be arbitrary such as for example rectangular, octagonal, elliptical and so forth. Assuming an octagonal shape for the vacuum gap 143, such as shown in FIG. 11, the typical dimensions may vary from 20 nm to 200 um. The typical thickness of the vacuum gap 143 may vary from 1 nm to 500 nm. The typical thicknesses of the top conductor 141, contact conductors 144, 145, 146 and 147, and the actuation conductor 149 may vary from 50 nm to 10 um. The typical thickness of the insulator layer 148 may vary from 1 nm to 500 nm. The lateral size and shape of the actuation electrode 149 may vary as discussed separately, however the size is typically equivalent or smaller than that of the vacuum gap 143. An opening or several openings in the actuation conductor 149 are left so that the contact conductors 144, 145, 146 and 147 have access to the bottom interconnection 152.

The manufacturing of the invention of can be done by using conventional thin film processing techniques with compatible materials, for example: silicon, gallium arsenide, glass, quartz or sapphire as the carrier material 153; gold, tungsten, copper, aluminum or polysilicon as the conductor material for the top conductor 141, contact conductors 144, 145, 146 and 147, bottom interconnection 152, and the actuation conductor 149; silicon oxide, silicon nitride, tantalum nitride, or low-k dielectric for the insulator layers 142, 148, 150 and 151. The carrier material 153 may contain several layers of a microelectronic circuit containing other devices on and/or below it.

Comparing single vacuum gap device 120 and single vacuum gap device 140, the latter has more flexibility in optimizing the switch off-state parasitic capacitance between the top conductor 141 and the contact conductors 144, 145, 146 and 147 against the contact resistance between said elements in the switch on-state.

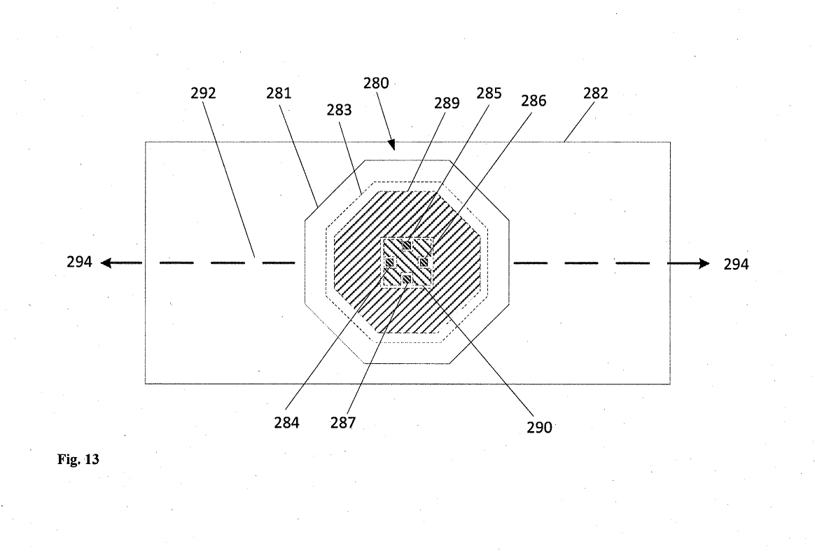

Referring now to the invention shown in FIG. 12 and FIG. 13, there is shown a single vacuum gap device 280 having a top conductor 281 that is on the top of an insulator layer 282 and the vacuum gap 283. The top conductor 281 is covering the vacuum gap 283 area so that it is hermetically sealed. The bottom of the vacuum gap 283 is limited by an insulator layer 288 and the contact conductors 284, 285, 286 and 287. Actuation conductors 289 and 290 are below the insulator layer 288 and on top of an insulator layer 291. A bottom interconnection 293 and single vacuum gap device 280 are on top of a carrier material 294. The insulator layer 292 provides physical separation between the bottom interconnection 293 and the other conductors and may consist of several separate insulator layers. The location of cross-sectioning for FIG. 12 is shown by the dashed line 294 in FIG. 13. The area containing the actuation conductors 289 and 290 is shown magnified in FIG. 14.

In more detail, still referring to the invention of FIG. 12 and FIG. 13, the top conductor 281, the insulator layer 288, the vacuum gap 283, the contact conductors 284, 285, 286 and 287, and the actuation conductors 289 and 290 form a mechanical switch. The top conductor 281 can be actuated by electrostatic force so that it is moved down against the contact conductors 284, 285, 286 and 287 forming an ohmic contact. The electrostatic force can be generated for example by applying actuation voltages between the top conductor 281 and the actuation conductors 289 and 290. The insulator layer 288 will prevent an electrical contact between the top conductor 281 and the actuation conductors 289 and 290, so it is possible to pull down the top conductor 281 without causing a short circuit. The switch is in open state when actuation voltage between the top conductor 281 and actuation conductors 289 and 290 is low (ideally 0 V), and in closed state when the actuation voltages are such that they will pull down and hold the top conductor 281. The actuation voltages can be separate time domain waveforms that optimize the dynamic transition of the switch from off to on state and vice versa in order to minimize contact bouncing, ringing as well as contact resistance and stiction. This is achieved by applying separate voltage to the actuation conductors 289 and 290.

In further detail, still referring to the invention of FIG. 12 and FIG. 13, the lateral geometry of the vacuum gap 283 may be arbitrary such as for example rectangular, octagonal, elliptical and so forth. Assuming an octagonal shape for the vacuum gap 283, such as shown in FIG. 12, the typical dimensions may vary from 20 nm to 200 um. The typical thickness of the vacuum gap 283 may vary from 1 nm to 500 nm. The typical thicknesses of the top conductor 281, contact conductors 284, 285, 286 and 287, and the actuation conductors 289 and 290 may vary from 50 nm to 10 um. The typical thickness of the insulator layer 288 may vary from 1 nm to 500 nm. The lateral size and shape of the actuation electrodes 289 and 290 may vary as discussed separately, however the size is typically equivalent or smaller than that of the vacuum gap 283. An opening or several openings in the actuation conductors 289 and 290 are left so that the contact conductors 284, 285, 286 and 287 have access to the bottom interconnection 293.

The manufacturing of the invention of can be done by using conventional thin film processing techniques with compatible materials, for example: silicon, gallium arsenide, glass, quartz or sapphire as the carrier material 289; gold, tungsten, copper, aluminum or polysilicon as the conductor material for the top conductor 281, contact conductors 284, 285, 286 and 287, bottom interconnection 293, and the actuation conductors 289 and 290; silicon oxide, silicon nitride, tantalum nitride, or low-k dielectric for the insulator layers 282, 288, 291 and 292. The carrier material 294 may contain several layers of a microelectronic circuit containing other devices on and/or below it.

Comparing single vacuum gap device 140 and single vacuum gap device 280, the latter has more flexibility in controlling the dynamic movement of the top conductor 281 during actuation. Also the distribution of the contact force between the top conductor 281 and contact conductors 284, 285, 286 and 287 while the switch is closed, can be better controlled by applying appropriate actuation voltage levels or waveforms to the actuation conductors 289 and 290.

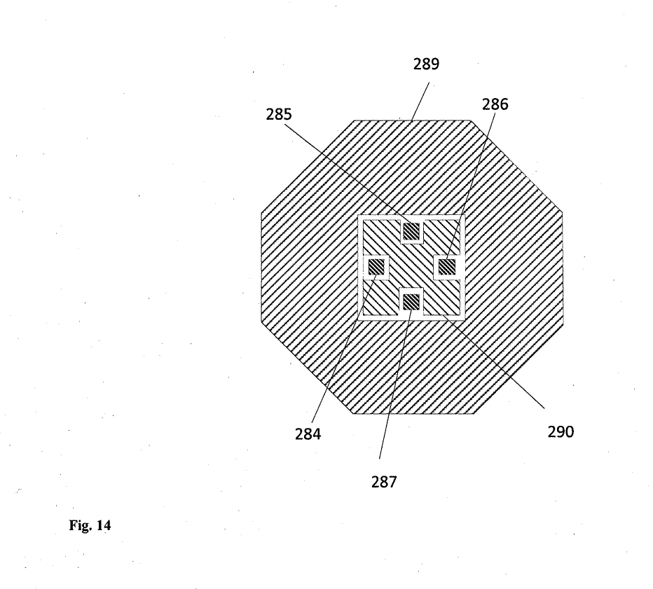

Referring now to the invention shown in FIG. 15, there is shown a double vacuum gap device 300 having a top conductor 301 that is on the top of an insulator layer 302 and an upper vacuum gap 303. The top conductor 301 is covering the upper vacuum gap 303 area so that it is hermetically sealed. The bottom of the upper vacuum gap 303 is limited by a middle conductor 304 that is on the top of the insulator layer 305. The bottom of the lower vacuum gap 306 is limited by the insulator layer 309 and the contact conductors 307 and 308. The actuation conductor 311 is below the insulator layer 309 and on top of an insulator layer 310. A bottom interconnection 313 and double vacuum gap device 300 are on top of a carrier material 314. An insulator layer 312 provides physical separation between a bottom interconnection 313 and the other conductors and may consist of several separate insulator layers. The top conductor 301 and middle conductor 304 may be electrically connected with additional interconnections. In addition there may be an insulating layer between the top conductor 301 and the upper vacuum gap 303.

In more detail, still referring to the invention of FIG. 15, the top conductor 301, the middle conductor 304, the insulator layer 309, the upper vacuum gap 303, the lower vacuum gap 306, the contact conductors 307 and 308, and the actuation conductor 311 form a mechanical switch. The middle conductor 304 can be actuated by electrostatic force so that it is moved down against the contact conductors 307 and 308 forming an ohmic contact. The electrostatic force can be generated for example by applying actuation voltage between the middle conductor 304 and the actuation conductor 311. The insulator layer 309 will prevent an electrical contact between the middle conductor 304 and the actuation conductor 311, so it is possible to pull down the middle conductor 304 without causing a short circuit. The switch is in open state when actuation voltage between the middle conductor 304 and actuation conductor 311 is low (ideally 0 V), and in closed state when the actuation voltage is such that it will pull down and hold the middle conductor 304. The middle conductor 304 can also be actuated by applying an actuation voltage between it and the top conductor 301.

In further detail, still referring to the invention of FIG. 15, the lateral geometry of the upper vacuum gap 303 and lower vacuum gap 306 may be arbitrary such as for example rectangular, octagonal, elliptical and so forth and different from each other. Assuming an octagonal shape for the upper vacuum gap 303 and lower vacuum gap 306, the typical dimensions may vary from 20 nm to 200 um. The typical thicknesses of the upper vacuum gap 303 and lower vacuum gap 306 may vary from 1 nm to 500 nm. The typical thicknesses of the top conductor 301, middle conductor 304, contact conductors 307 and 308, and the actuation conductor 311 may vary from 50 nm to 10 um. The typical thickness of the insulator layer 309 may vary from 1 nm to 500 nm. The lateral size and shape of the actuation electrode 311 may vary as discussed separately, however the size is typically equivalent or smaller than that of the lower vacuum gap 306. An opening or several openings in the actuation conductor 311 is left so that the contact conductors 307 and 308 have access to the bottom interconnection 313.

The manufacturing of the invention can be done by using conventional thin film processing techniques with compatible materials, for example: silicon, gallium arsenide, glass, quartz or sapphire as the carrier material 314; gold, tungsten, copper, aluminum or polysilicon as the conductor material for the top conductor 301, middle conductor 304, contact conductors 307 and 308, bottom interconnection 313, and the actuation conductor 311; silicon oxide, silicon nitride, tantalum nitride, or low-k dielectric for the insulator layers 302, 305, 309, 310 and 312. The carrier material 314 may contain several layers of a microelectronic circuit containing other devices on and/or below it.

Comparing single vacuum gap device 280 and double vacuum gap device 300, the latter has a possibility to actuate the moving part, i.e. the middle conductor 304 both up and down, so it is possible to for example to lock the middle conductor 304 in off-state so that the switch will not self-actuate, and also to actively pull up the middle conductor 304 from switch on-state when it is released, with electrostatic force and/or van der Waals forces. The top conductor 301 can prevent ringing of the switch by mechanical damping if the upper vacuum gap 303 thickness is small enough. The top conductor 301 can protect the middle conductor 304 from external pressure and smaller than lower gap? The upper vacuum gap 303 can increase the mechanical quality factor of the middle conductor 304 if it is used as a resonator.

Referring now to the invention shown in FIG. 16, there is shown a single vacuum gap device 330 having a top conductor 331 that is on the top of the insulator layer 332 and the vacuum gap 333. The top conductor 331 is covering the vacuum gap 330 area so that it is hermetically sealed. The bottom of the vacuum gap 330 is limited by the contact conductor 335 and the insulator layer 334. The actuation conductor 336 is below the insulator layer 334 and on top of the insulator layer 337. The bottom interconnection 338 and single vacuum gap device 330 are on top of the carrier material 339.

In more detail, still referring to the invention of FIG. 16, a top conductor 331, an insulator layer 334, a vacuum gap 333, a contact conductor 335, and an actuation conductor 336 form a mechanical switch. The top conductor 331 can be actuated by electrostatic force so that it is moved down to the close proximity of the contact conductor 335 forming a high conduction path between the two conductors without necessarily forming a mechanical contact. The electrostatic force can be generated for example by applying actuation voltage between the top conductor 331 and the actuation conductor 336. The insulator layer 334 prevents an electrical contact between the top conductor 331 and the actuation conductor 336, so it is possible to pull down the top conductor 331 without causing a short circuit. The switch is in open state when actuation voltage between the top conductor 331 and actuation conductor 336 is low (ideally 0 V), and in closed state when the actuation voltage is such that it will pull down and hold the top conductor 331. Although not shown in the figure, the top conductor 331 may have a protrusion above the contact conductor 335 so that the distance between these conductors is smaller than the thickness of the insulator layer 334 while the single vacuum gap device 330 is in actuated state; also the contact conductor 335 may extend above the surface of the insulator layer 337 with similar effect.

In further detail, still referring to the invention of FIG. 16, the lateral geometry of the vacuum gap 333 may be arbitrary such as for example rectangular, octagonal, elliptical and so forth. Assuming an octagonal shape for the vacuum gap 333 the typical width may vary from 20 nm to 200 um. The typical thicknesses of the vacuum gap 333 may vary from 1 nm to 500 nm. The typical thicknesses of the top conductor 331, contact conductor 335, and the actuation conductor 336 may vary from 50 nm to 10 um. The typical thickness of the insulator layer 334 may vary from 1 nm to 500 nm. The lateral size and shape of the actuation electrode 336 may vary as discussed separately, however the size is typically equivalent or smaller than that of the vacuum gap 333. An opening or several openings in the actuation conductor 336 is left so that the contact conductor 335 has access to the bottom interconnection 338.

The manufacturing of the invention of can be done by using conventional thin film processing techniques with compatible materials, for example: silicon, gallium arsenide, glass, quartz or sapphire as the carrier material 339; gold, tungsten, copper, aluminum or polysilicon as the conductor material for the top conductor 331, contact conductor 335, bottom interconnection 338, and the actuation conductor 336; silicon oxide, silicon nitride, tantalum nitride, or low-k dielectric for the insulator layers 332, 334 and 337. The carrier material 339 may contain several layers of a microelectronic circuit containing other devices on and/or below it.

Comparing single vacuum gap device 120 and single vacuum gap device 330, the latter has a possibility of forming an electrical contact without forming a mechanical contact between the top conductor and the contact conductor. This increases the reliability of the device as the contact is more repeatable since the probability of microwelding of contact areas and deformation of conductors is smaller.

### All Switches

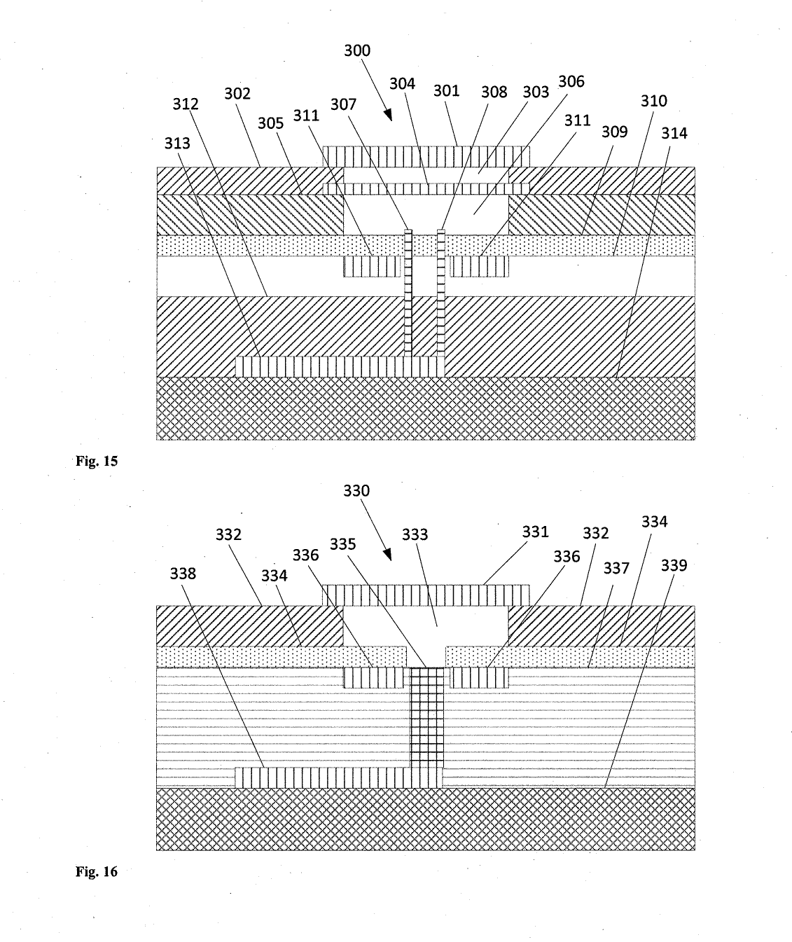

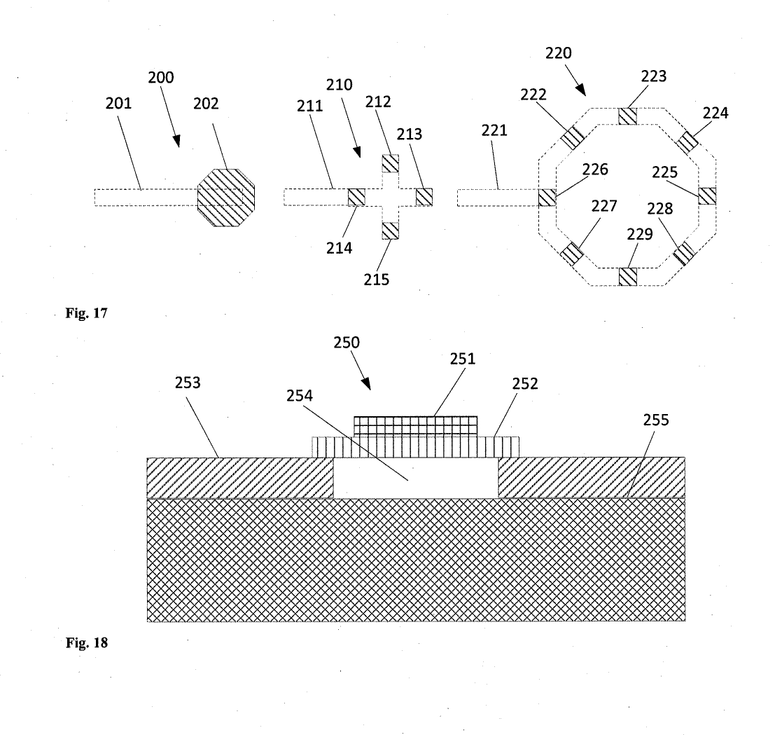

Referring to all vacuum gap based devices described above that can be used as a switch, the contact conductor or conductors may have different configurations with arbitrary lateral shape and number of contacts. The location of the contact conductors can be chosen so that the ohmic contact resistance of the switch is minimized when the switch is in on-state. FIG. 17 shows a top view of three possible configurations for the contact conductors. In configuration 200 there is a straight bottom interconnection 201 and a single contact conductor 202. In configuration 210 there is a bottom interconnection 211 with a plus shape at the end connecting the contact conductors 212, 213, 214 and 215. In configuration 220 there is a bottom interconnection 221 with an octagonal ring connecting the eight contact conductors 222-229.

Referring still to all vacuum gap based devices of this document that can be used as a switch, the lateral size and shape as well as the number of the actuation electrodes may vary so that the actuation force that pulls down the top conductor can be dynamically controlled. One possible application is to control the switching from off to on-state so that the top conductor will not experience pull-in i.e. it will not collapse against the substrate at the bottom of the vacuum gap. This can be done by applying appropriate actuation voltage waveforms to each actuation electrode so that the electrostatic force does not increase too much as the top conductor approaches the actuation electrodes. This can eliminate switch bouncing as the speed of the top conductor at the time of forming contact can be reduced greatly.

Referring still to all vacuum gap based devices described above that can be used as a switch, the device can also be used: for sensing as a tunneling device, where the tunneling happens between the contact and the conductor above it, or between any conductors that are separated by a vacuum gap and are at least temporarily close enough to each other to allow tunneling current; as a tunable capacitor.

### Double Vacuum Gap Devices

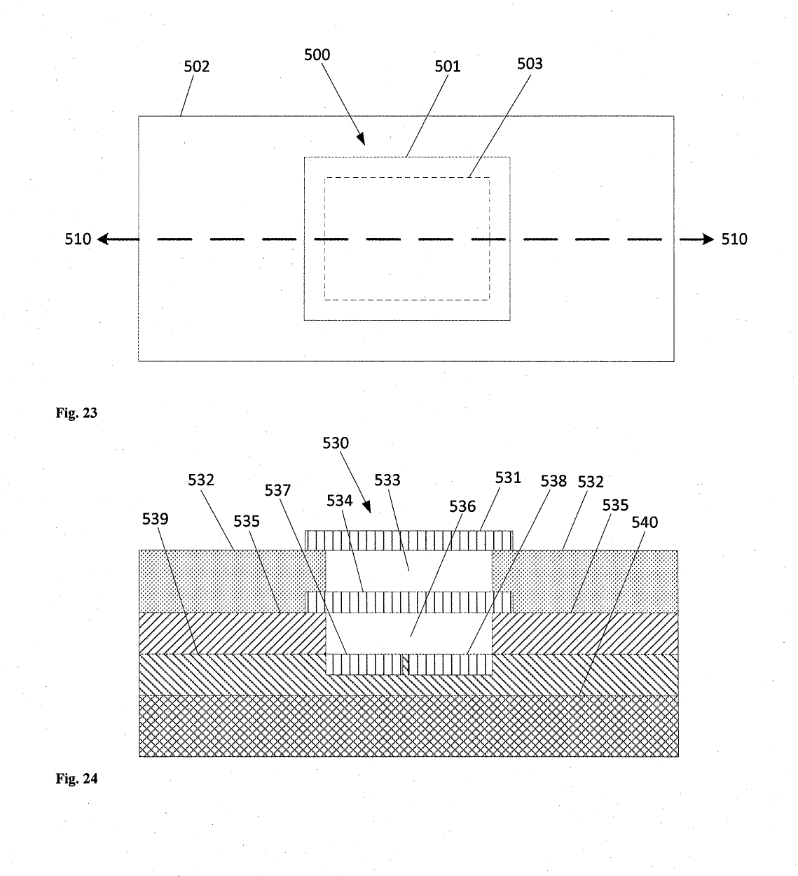

Referring now to the invention shown in FIG. 22 and FIG. 23 there is shown a double vacuum gap device 500 having a top conductor 501 that is on the top of an insulator layer 502 and an upper vacuum gap 503. The top conductor 501 is covering the upper vacuum gap 503 area so that it is hermetically sealed. The bottom of the upper vacuum gap 503 is limited by a bottom conductor 504. The bottom conductor 504 is on top of an insulator layer 505 and/or lower vacuum gap 506. The bottom of the lower vacuum gap 506 is limited by an insulator layer 507. The double vacuum gap device 500 is above a carrier material 508. The location of cross-sectioning for FIG. 22 is shown by the dashed line 510 in FIG. 23.

In more detail, still referring to the invention of FIG. 22 and FIG. 23, the top conductor 501, the upper vacuum gap 503, the lower vacuum gap 506 and the bottom conductor 504 form an electrical device that can be a mechanical resonator or a capacitor. For a capacitor device the thickness of the upper vacuum gap 503 can vary as a function of an external pressure that is applied on the top conductor 101 or as a function of electrostatic force. The electrostatic force can be generated for example by applying an actuation voltage between the top conductor 501 and the bottom conductor 504. The electrostatic force will attract the top conductor 501 and the bottom conductor 504 closer to each other. As a result the electrical properties of the double vacuum gap device 500 will change so that in the capacitance of the double vacuum gap device 500 will increase as the thickness of the upper vacuum gap 503 decreases. As a capacitor device the double vacuum gap device 500 can be used for example as a sensor to measure the ambient pressure or as an electrically controlled variable capacitor in an electrical circuit. In a resonator device the top conductor 501 and/or the bottom conductor 504 act as a mechanical resonator that may be actuated by applying an AC voltage between the top conductor 501 and bottom conductor 504. The upper vacuum gap 503 and the lower vacuum gap 506 provide the space that is needed for the displacement of the top conductor 501 and/or bottom conductor 504.

In further detail, still referring to the invention of FIG. 22 and FIG. 23, the lateral geometry of the upper vacuum gap 503 and lower vacuum gap 506 may be arbitrary such as for example rectangular, octagonal, elliptical and so forth. Assuming a rectangular shape for the upper vacuum gap 503 and lower vacuum gap 506 the typical dimensions may vary from 20 nm to 200 um. The typical thicknesses of the upper vacuum gap 503 and lower vacuum gap 506 may vary from 0.5 Å to 100 Å for quantum tunneling applications and from 5 nm to 500 nm for capacitive applications. The typical thicknesses of the top conductor 501 and bottom conductor 504 may vary from 5 nm to 10 um.

The manufacturing of the invention of FIG. 22 and FIG. 23 can be done by using conventional thin film processing techniques with compatible materials, for example: silicon, gallium arsenide, glass, quartz or sapphire as the carrier material 508; gold, tungsten, copper, aluminum or polysilicon as the conductor material for the top conductor 501 and the bottom conductor 504; silicon oxide, silicon nitride, low-k dielectric or tantalum oxide for the insulator layers 502, 505 and 507. The carrier material 508 may be for example a semiconductor substrate, glass, quartz or a layer of a microelectronic circuit containing other devices on and/or below it.

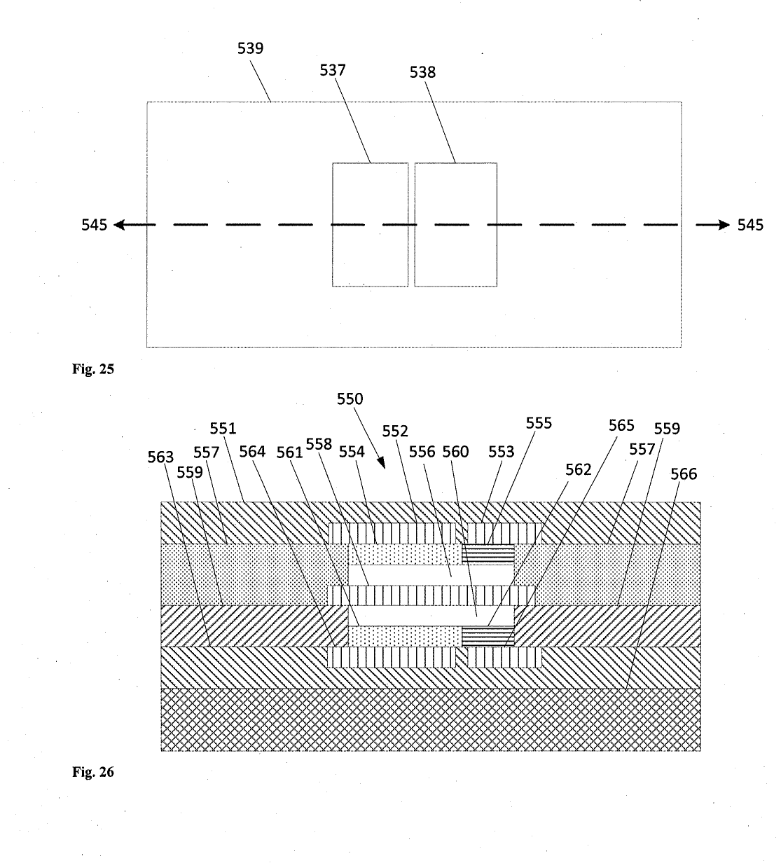

Referring now to the invention shown in FIG. 24 and FIG. 25 there is shown a double vacuum gap device 530 having a top conductor 531 that is on the top of an insulator layer 532 and an upper vacuum gap 533. The top conductor 531 is covering the upper vacuum gap 533 area so that it is hermetically sealed. The bottom of the upper vacuum gap 533 is limited by a middle conductor 534. The middle conductor 534 is on top of an insulator layer 535 and/or a lower vacuum gap 536. The bottom of the lower vacuum gap 536 is limited by an insulator layer 537 and bottom conductors 537 and 538. The double vacuum gap device 530 is above carrier material 540. The location of cross-sectioning for FIG. 25 is shown by the dashed line 545 in FIG. 25. FIG. 24 shows a top view of the double vacuum gap device 530 with bottom conductors 537 and 538, other parts are omitted for clarity.

In more detail, still referring to the invention of FIG. 24 and FIG. 25, the top conductor 531, the upper vacuum gap 533, the middle conductor 534, the lower vacuum gap 536 and the bottom conductors 537 and 538 form an electrical device that can be a mechanical resonator or a capacitor. For a capacitor device the thickness of the upper vacuum gap 533 can vary as a function of an external pressure that is applied on the top conductor 531 or as a function of electrostatic force. The electrostatic force can be generated for example by applying an actuation voltage between the top conductor 531 and the middle conductor 534. The electrostatic force will attract the top conductor 531 and the middle conductor 534 closer to each other. As a result the electrical properties of the double vacuum gap device 531 will change so that the capacitance of the double vacuum gap device 530 will increase as the thickness of the upper vacuum gap 533 decreases. As a capacitor device the double vacuum gap device 530 can be used for example as a sensor to measure the ambient pressure or as an electrically controlled variable capacitor in an electrical circuit. In a resonator device the top conductor 531 and/or the middle conductor 534 act as a mechanical resonator that may be actuated by applying an AC voltage between the top conductor 531 and middle conductor 534. The upper vacuum gap 533 and the lower vacuum gap 536 provide the space that is needed for the displacement of the top conductor 531 and/or middle conductor 534. In addition the actuation of the middle conductor can be done by applying an actuation voltage between the middle conductor 534 and the bottom conductor 537 and/or bottom conductor 538. The movement and/or position of the middle conductor 534 can be measured by detecting the capacitance or tunneling current between the middle conductor 534 and the bottom conductor 537 and/or bottom conductor 538. Instead of having two bottom conductors, the number of bottom conductors may vary from one to many for both actuation and/or sensing purposes.

In further detail, still referring to the invention of FIG. 24 and FIG. 25, the lateral geometry of the upper vacuum gap 533 and lower vacuum gap 536 may be arbitrary such as for example rectangular, octagonal, elliptical and so forth. Assuming a rectangular shape for the upper vacuum gap 533 and lower vacuum gap 536 the typical dimensions may vary from 20 nm to 200 um. The typical thicknesses of the upper vacuum gap 533 and lower vacuum gap 536 may vary from 0.5 Å to 100 Å for quantum tunneling applications and from 5 nm to 500 nm for capacitive applications. The typical thicknesses of the top conductor 531, middle conductor 534 and bottom conductors 537 and 538 may vary from 5 nm to 10 um.

The manufacturing of the invention of FIG. 24 and FIG. 25 can be done by using conventional thin film processing techniques with compatible materials, for example: silicon, gallium arsenide, glass, quartz or sapphire as the carrier material 540; gold, tungsten, copper, aluminum or polysilicon as the conductor material for the top conductor 531, middle conductor 534 and bottom conductors 537 and 538; silicon oxide, silicon nitride, low-k dielectric or tantalum oxide for the insulator layers 532, 535 and 539. The carrier material 540 may be for example a semiconductor substrate, glass, quartz or a layer of a microelectronic circuit containing other devices on and/or below it.

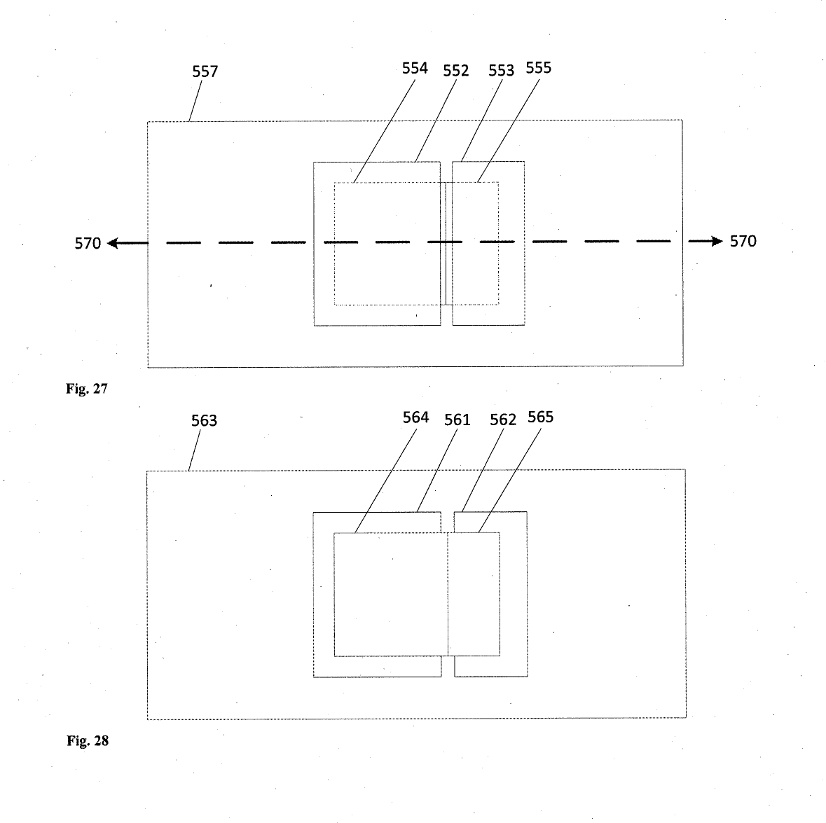

Referring now to the invention shown in FIG. 26-FIG. 28 there is shown an embedded double vacuum gap device 550 having an insulator layer 551 covering the device, isolated top conductor 552 and electrically connected top conductor 553 to where? The isolated top conductor 552 is on the top of an insulator layer 557 and/or an upper vacuum gap top insulator 554. The connected top conductor 553 is on top of the upper vacuum gap contact conductor 555 and/or the insulator layer 557 and/or an upper vacuum gap top insulator 554. An upper vacuum gap 556 is limited by the upper vacuum gap top insulator 554 and an upper vacuum gap contact conductor 555, an insulator layer 557 and a middle conductor 558 that separates the upper vacuum gap 556 and a lower vacuum gap 560. The lower vacuum gap 560 is limited by the middle conductor 558, an insulator layer 559, a lower vacuum gap bottom insulator 561 and a lower vacuum gap contact conductor 562. An isolated bottom conductor 564 is below a lower vacuum gap bottom insulator 561 and/or an insulator layer 559. A connected bottom conductor 565 is below a lower vacuum gap contact conductor 562 and/or an insulator layer 559 and/or the lower vacuum gap bottom insulator 561. The embedded double vacuum gap device 550 is above a carrier material 566. The location of cross-sectioning for FIG. 26 is shown by the dashed line 570 in FIG. 27. FIG. 27 shows a top view of the embedded double vacuum gap device 550 with the named parts related to the upper vacuum gap 556; other parts are omitted for clarity. FIG. 28 shows a top view of the embedded double vacuum gap device 550 with the named parts related to the lower vacuum gap 560; other parts are omitted for clarity.

In more detail, still referring to the invention of FIG. 26-FIG. 28, the isolated top conductor 552, connected top conductor 555, upper vacuum gap top insulator 554, upper vacuum gap contact conductor 555, upper vacuum gap 556, middle conductor 558, lower vacuum gap 560, lower vacuum gap bottom insulator 561, lower vacuum gap contact conductor 562, isolated bottom conductor 564 and connected bottom conductor 565 form the functional device that can be used for example as a (Single Pole Double Throw) SPDT switch. The middle conductor 558 can be electrostatically actuated by applying an actuation voltage between the isolated top conductor 552 and the middle conductor 558 so that an ohmic contact is formed between the upper vacuum gap contact conductor 555 and the middle conductor 558. Alternatively the middle conductor 558 can be electrostatically actuated by applying an actuation voltage between the isolated bottom conductor 564 and the middle conductor 558 so that an ohmic contact is formed between the lower vacuum gap contact conductor 562 and the middle conductor 558. In the third state the middle conductor 558 can rest in the center position without ohmic contact e.g. when no actuation voltage is applied to the isolated conductors 552 and 564. In these actuation states the embedded dual vacuum gap device 550 will act as an SPDT switch so that it is conducting only between the middle conductor 558 and the connected top conductor 553, conducting only between the middle conductor 558 and the connected bottom conductor 565, and not conducting between the middle conductor 558 and the other conductors, respectively. Another mode of operation may be configured by applying a high voltage to the isolated top conductor 552 and a low voltage to the isolated bottom conductor 564 and providing an actuation voltage to the middle conductor 558. In case of low actuation voltage the electrostatic force pulls the middle conductor 558 up so that an ohmic contact is formed between the middle conductor 558 and the upper vacuum gap contact conductor 555. In case of high actuation voltage the electrostatic force pulls the middle conductor 558 down so that an ohmic contact is formed between the middle conductor 558 and the lower vacuum gap contact conductor 562. In case of actuation voltage half-way between high and low voltage the electrostatic forces will be canceled so that the middle conductor 558 stays in center position and forms no ohmic contact.

In further detail, still referring to the invention of FIG. 26-FIG. 28, the lateral geometry of the upper vacuum gap 556 and lower vacuum gap 560 may be arbitrary such as for example rectangular, octagonal, elliptical and so forth. Assuming a rectangular shape for the upper vacuum gap 556 and lower vacuum gap 560 the typical dimensions may vary from 20 nm to 200 um. The typical thicknesses of the upper vacuum gap 556 and lower vacuum gap 560 may vary from 0.5 Å to 100 Å for quantum tunneling applications and from 5 nm to 500 nm for switch applications. The typical thicknesses of the isolated top conductor 552, connected top conductor 555, upper vacuum gap top insulator 554, upper vacuum gap contact conductor 555, middle conductor 558, lower vacuum gap bottom insulator 561, lower vacuum gap contact conductor 562, isolated bottom conductor 564 and connected bottom conductor 565 may vary from 5 nm to 10 um.

The manufacturing of the invention of FIG. 26-FIG. 28 can be done by using conventional thin film processing techniques with compatible materials, for example: silicon, gallium arsenide, glass, quartz or sapphire as the carrier material 566; gold, tungsten, copper, aluminum or polysilicon as the conductor material for the isolated top conductor 552, connected top conductor 553, middle conductor 558, upper vacuum gap contact conductor 555, lower vacuum gap contact conductor 562 and isolated bottom conductor 564; silicon oxide, silicon nitride, low-k dielectric or tantalum oxide for the insulator layers 551, 557, 559 and 563 as well as the upper vacuum gap top insulator 554 and lower vacuum gap bottom insulator 561. The carrier material 566 may be for example a semiconductor substrate, glass, quartz or a layer of a microelectronic circuit containing other devices on and/or below it. There may be additional circuitry on top of the insulator layer 551.

### Multiple Vacuum Gap Devices

In the same manner as it is possible to make a double vacuum gap device instead of a single vacuum gap device, it is also possible to implement a vacuum gap device or a combination of vacuum gap devices by making three or more vacuum gaps on top of each other. In this case of multiple vacuum gap device the structure contains parts that may move mechanically on two or more layers. In addition to actuation by the static conductors it is also possible to have electrostatic forces, mechanical forces, interacting between the mechanically moving parts and used for actuation or control for sensing. In addition to the interactions between moving and static parts, the tunneling current(s), capacitance(s), transfer function(s) such as frequency response between the moving parts can be used for sensing applications. Each moving part may have same or different mechanical resonance frequency as the others.

### Surface Cantilever Devices

The cantilever structures are not using a vacuum gap as there is no closed cavity related to the device. However the processing steps to provide the gap below the cantilever are similar to making a vacuum gap.

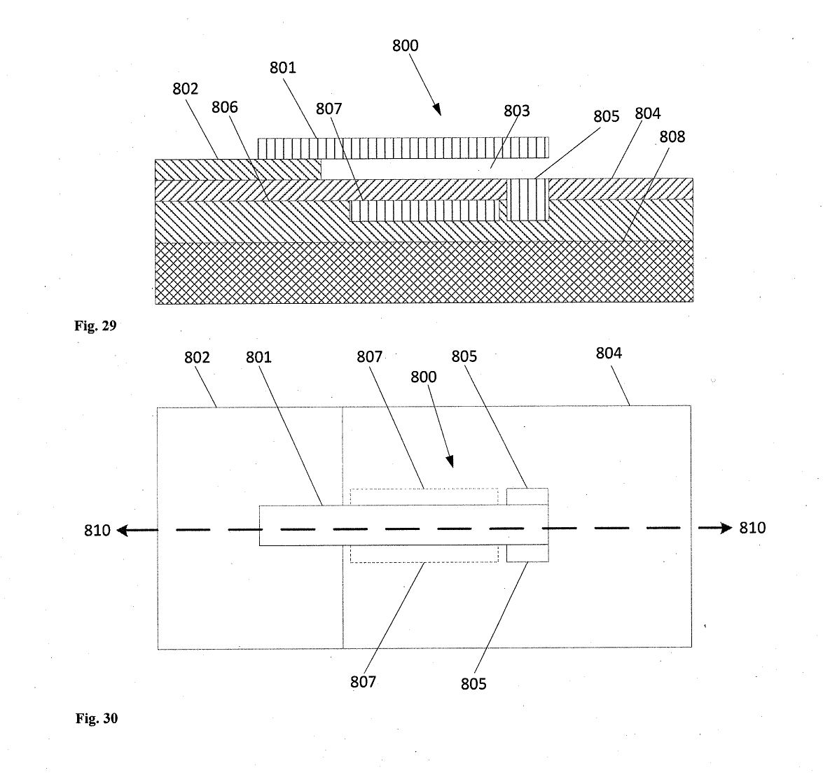

Referring now to the invention shown in FIG. 29 and FIG. 30 there is shown a single gap cantilever device 800 having a top conductor 801 that is on the top of an insulator layer 802 and a gap 803. The bottom of the gap 803 is limited by an insulator layer 804 and a contact conductor 805. An actuation conductor 807 is below the insulator layer 804 and on top of an insulator layer 806. The single gap cantilever device 800 is above a carrier material 808. The location of cross-sectioning for FIG. 29 is shown by the dashed line 810 in FIG. 30.

In more detail, still referring to the invention of FIG. 29 and FIG. 30, the top conductor 801, the insulator layers 802 and 804, the gap 803, the contact conductor 805 and the actuation conductor 807 form a cantilever device that can be used for example as a mechanical switch. The top conductor 801 can be actuated by electrostatic force so that it is moved down against the contact conductor 805 forming an ohmic contact. The electrostatic force can be generated for example by applying an actuation voltage between the top conductor 801 and the actuation conductor 807. The insulator layer 805 will prevent an electrical contact between the top conductor 801 and the actuation conductor 807, so it is possible to pull down the top conductor 801 without causing a short circuit. The device acts as a switch in open state when actuation voltage between the top conductor 801 and actuation conductor 807 is low (ideally 0 V), and a switch in closed state when the actuation voltage is such that it will pull down and hold the top conductor 801 so that it forms an ohmic contact with the contact conductor 805.

In further detail, still referring to the invention of FIG. 29 and FIG. 30, the lateral geometry of the top conductor 801 may be arbitrary such as for example rectangular. Assuming a rectangular shape for the top conductor 801, such as shown in FIG. 30, the typical dimensions may vary from 20 nm to 200 um. The typical thicknesses of the gap 803 and the insulator layer 802 may vary from 1 nm to 500 nm. The typical thicknesses of the top conductor 801, contact conductor 805 and the actuation conductor 807 may vary from 50 nm to 10 um. The typical thickness of the insulator layer 804 may vary from 1 nm to 500 nm. The lateral size and shape of the actuation electrode 807 may vary, however the size is typically equivalent or smaller than that of the gap 803. The actuation conductor 807 may be located directly below the gap 803 without having any insulator layer on top of it; in this case the single gap cantilever device 800 may be designed so that there will be no ohmic contact but instead a sufficient physical separation between the top conductor 801 and the actuation electrode 807 when the device is used as a switch and the switch is in closed state.

The manufacturing of the invention of FIG. 29 and FIG. 30 can be done by using conventional thin film processing techniques with compatible materials, for example: silicon, gallium arsenide, glass, quartz or sapphire as the carrier material 808; gold, tungsten, copper, aluminum or polysilicon as the conductor material for the top conductor 801, contact conductor 805 and the actuation conductor 807; silicon oxide, silicon nitride, tantalum nitride, or low-k dielectric for the insulator layers 802, 804 and 806. The carrier material 808 may contain several layers of a microelectronic circuit containing other devices on and/or below it.

Referring now to the invention shown in FIG. 31 and FIG. 32 there is shown a single gap cantilever device with lateral actuation 850 having a top conductor 851 that is on the top of an insulator layer 852 and a gap 853. The bottom of the gap 853 is limited by a diffusion plate 858 that is used to form the gap 853. The diffusion plate 858 is embedded or on top of an insulator layer 859. The diffusion layer can be used for storing charge. The charge carriers can change their locations due to physical diffusion process. Contacts 854 and 856 and the cantilever 851 can be used to change electromagnetic field over the diffusion layer. The change of the electromagnetic field will lead to change of the position of the charge carriers stored at the diffusion layer 858. The contacts 855 and 857 are used for conducting the stored charge. Actuation conductors 854 and 856 are on top of an insulator layer 852. The contact conductors 855 and 857 are on top of the insulator layer 852 and may overlap the gap 853. The single gap cantilever device 800 is above the carrier material 808. The location of cross-sectioning for FIG. 31 is shown by the dashed line 810 in FIG. 32.

In more detail, still referring to the invention of FIG. 31 and FIG. 32, the top conductor 851, the insulator layer 852, the contact conductors 855 and 856, and the actuation conductors 854 and 855 form a cantilever device that can be used for example as a mechanical switch. The gap 853 provides the possibility of movement of the top conductor 851 that can act as a cantilever. The top conductor 851 may be actuated by electrostatic force so that it is moved against the contact conductor 855 forming an ohmic contact. The electrostatic force can be generated for example by applying an actuation voltage between the top conductor 851 and the actuation conductor 854. The electrostatic force can be generated in another direction by applying an actuation voltage between the top conductor 851 and the actuation conductor 856 so that an ohmic contact is formed between the top conductor 851 and the contact conductor 857. The single gap cantilever device with lateral actuation 850 may be used as a SPDT switch. In addition to the actuating a movement in the lateral plane (X-Y plane shown in FIG. 32) it is also possible to actuate the top conductor 851 by applying a voltage between the top conductor 851 and the diffusion plate 858 for example to release stiction when the top conductor is in contact with one of the contact conductors 855 and 857.

In further detail, still referring to the invention of FIG. 31 and FIG. 32, the lateral geometry of the top conductor 851 may be arbitrary such as for example rectangular or having extensions close to the contact conductors 855 and 856. Assuming a rectangular shape for the top conductor 851, such as shown in FIG. 31, the typical dimensions may vary from 20 nm to 200 um. The typical thicknesses of the gap 853 and the insulator layer 852 may vary from 1 nm to 500 nm. The typical thicknesses of the top conductor 851, contact conductors 855 and 857, and the actuation conductors 854 and 856 may vary from 50 nm to 10 um. The typical thicknesses of the insulator layer 859 and the diffusion plate 858 exceed the thickness of the gap 853 so that the gap 853 can be formed. The lateral size and shape of the actuation electrodes 854 and 856 may vary, however the X-dimension length typically smaller than that of the top conductor 851. The gap size has to be sufficient to provide enough space for the top conductor to move in respect to the contact conductors 855 and 857. The diffusion plate 858 typically needs to cover the whole area occupied by the gap 853.

The manufacturing of the invention of FIG. 31 and FIG. 32 can be done by using conventional thin film processing techniques with compatible materials, for example: silicon, gallium arsenide, glass, quartz or sapphire as the carrier material 860; gold, tungsten, copper, aluminum or polysilicon as the conductor material for the top conductor 851, contact conductors 855 and 857, actuation conductors 854 and 856, and diffusion plate 858; silicon oxide, silicon nitride, tantalum nitride, or low-k dielectric for the insulator layers 852 and 859. The carrier material 860 may contain several layers of a microelectronic circuit containing other devices on and/or below it.

### All Cantilever Devices

Referring to all gap based cantilever devices describe above that can be used as a switch, the contact conductor or conductors may have different configurations with arbitrary lateral shape and number of contacts. The location of the contact conductors can be chosen so that the ohmic contact resistance of the switch is minimized when the switch is in on-state.

Referring still to all gap based cantilever devices described above that can be used as a switch, the lateral size and shape as well as the number of the actuation electrodes may vary so that the actuation force that pulls the top conductor can be dynamically controlled. One possible application is to control the switching from off to on-state so that the top conductor will not experience pull-in i.e. it will not collapse against the adjacent surface in the direction of actuation. This can be done by applying appropriate actuation voltage waveforms to each actuation electrode so that the electrostatic force does not increase too much as the top conductor approaches the actuation electrodes. This can eliminate switch bouncing as the speed of the top conductor at the time of forming contact can be reduced greatly.

Referring still to all gap based cantilever devices described above that can be used as a switch, the cantilever structure can be used: for sensing as a tunneling device, where the tunneling happens between the contact and the conductor above it, or between any conductors that are separated by a vacuum gap and are at least temporarily close enough to each other to allow tunneling current; as a tunable capacitor.

### Static Vacuum Gap Devices

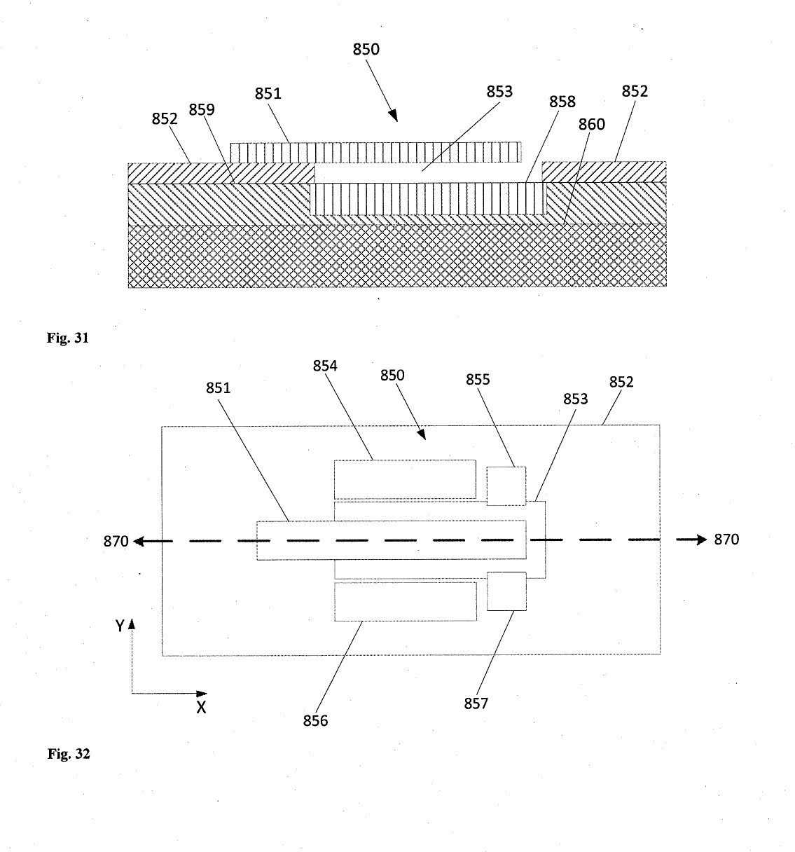

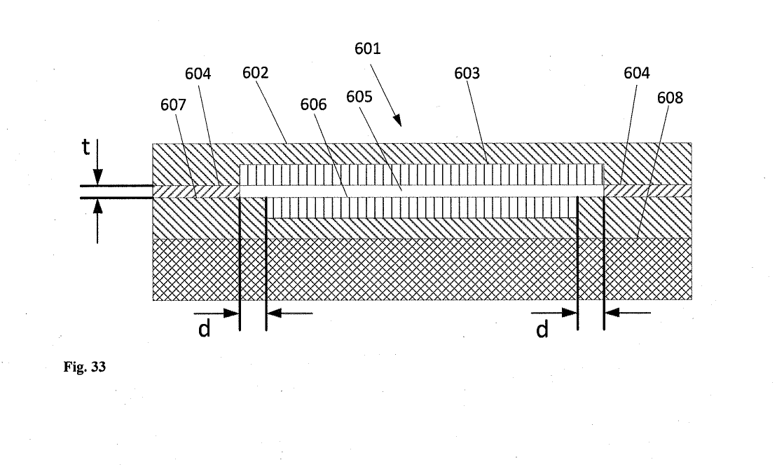

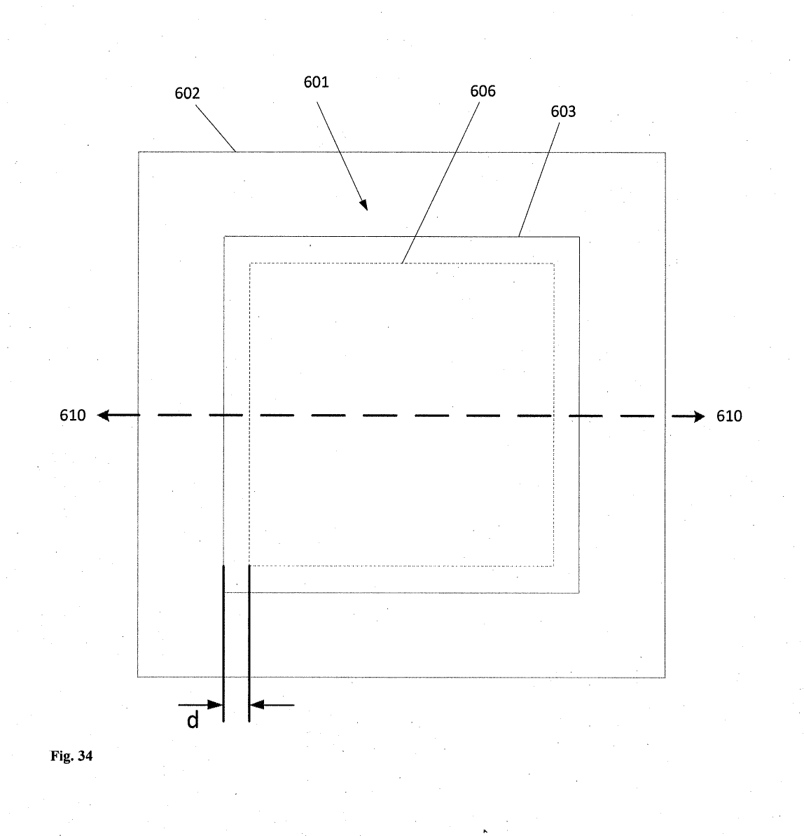

Referring now to the invention shown in FIG. 33 and FIG. 34 there is shown a single vacuum gap static capacitor 601 having a top electrode 603 that is on the top of a vacuum gap 605. The top electrode 603 and an insulator layer 602 are covering the vacuum gap 605 area so that it is hermetically sealed. The bottom of the vacuum gap 605 is limited by a bottom electrode 606 and a first insulator layer 607. The vacuum gap 605 is formed within a second insulator layer 604. The single vacuum gap static capacitor 601 is above a carrier material 608. The location of cross-sectioning for FIG. 33 is shown by the dashed line 610 in FIG. 34. The top electrode 603 may overlap the insulator layer 604.

In more detail, still referring to the invention of FIG. 33 and FIG. 34, the top electrode 603, the vacuum gap 605 and the bottom conductor 604 form an electrical device that can be a quantum tunneling device or a capacitor depending on the distance between the top electrode 603 and bottom electrode 606 i.e. the thickness t of the vacuum gap 605. The thickness t of the vacuum gap 605 is intended to stay constant during the operation of the device.

In further detail, still referring to the invention of FIG. 33 and FIG. 34, the lateral geometry of the vacuum gap 605 may be arbitrary such as for example rectangular, octagonal, elliptical and so forth. Typically the top electrode 603 and bottom electrode 606 have the same shape as the vacuum gap 605, although the top electrode 603 is same size or larger and the bottom electrode is typically smaller than the vacuum gap 605. The top electrode 603 needs to cover the whole vacuum gap 605 so that the material occupying the vacuum gap 605 before its formation can diffuse into the top electrode 603. Assuming a rectangular shape for the vacuum gap 605 the typical dimensions may vary from 1 um to 200 um. The typical thickness t of the vacuum gap 605 may vary from 0.5 Å to 100 Å for quantum tunneling applications and from 5 nm to 100 nm for capacitive applications. The typical thicknesses of the top electrode 603 and bottom electrode 606 may vary from 5 nm to 10 um. The bottom electrode 606 may have a smaller area than the vacuum gap 603 so that the vacuum gap 605 will overlap the bottom electrode 606 by a distance of d. This allows the concentration of an electric field between mainly in the vacuum area between top electrode 603 and bottom electrode 606 when the electrodes have a difference in electrostatic potential. The dimensions may be chosen so that the breakdown voltage between the top electrode 603 and bottom electrode 606 is higher through the dielectric materials i.e. first insulator layer 607 and second insulator 604 than through the vacuum gap 605, meaning that the distance d is significantly larger than the thickness t. The concentration of the electric field into the vacuum area provides high breakdown voltage for the device due to the properties of the vacuum. As a consequence the single gap vacuum gap static capacitor 601 can be used for example as a capacitor with high capacitance density and low leakage current in applications such as power storage, memory and conventional thin film capacitor applications.

The manufacturing of the invention of FIG. 33 and FIG. 34 can be done by using conventional thin film processing techniques with compatible materials, for example: silicon, gallium arsenide, glass, quartz or sapphire as the carrier material 608; tungsten, tungsten, copper, aluminum or polysilicon as the conductor material for the top electrode 603 and the bottom electrode 606; silicon oxide, silicon nitride or low-k dielectric for the insulator layers 602, 604 and 607. The carrier material 608 may be for example a semiconductor substrate, glass, quartz or a layer of a microelectronic circuit containing other devices on and/or below it.

Even though the invention of FIG. 33 and FIG. 34 is shown as a planar structure, the design can also apply three dimensional process technologies such as 3D damascene architectures to increase the capacitance density of the device. The key design aspects are sufficient thickness t for the vacuum gap so that the leakage current due to field electron emission is low enough, and sufficiently long minimum distance through the insulator material between the top and bottom electrodes to prevent unwanted electrical breakdown through the insulator.

### All Vacuum Gap Devices

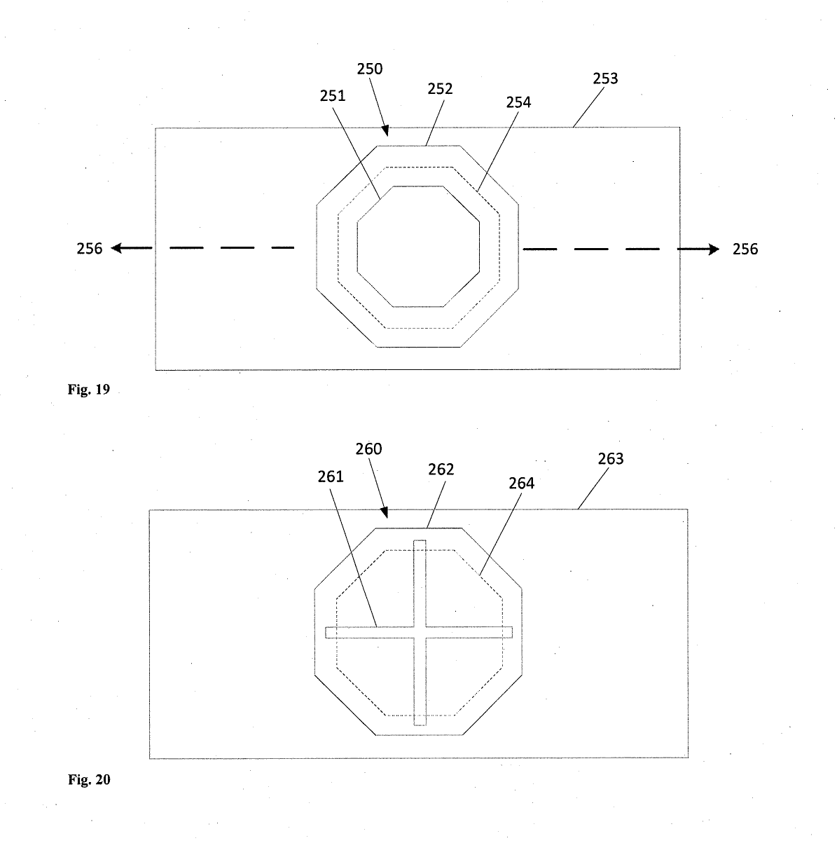

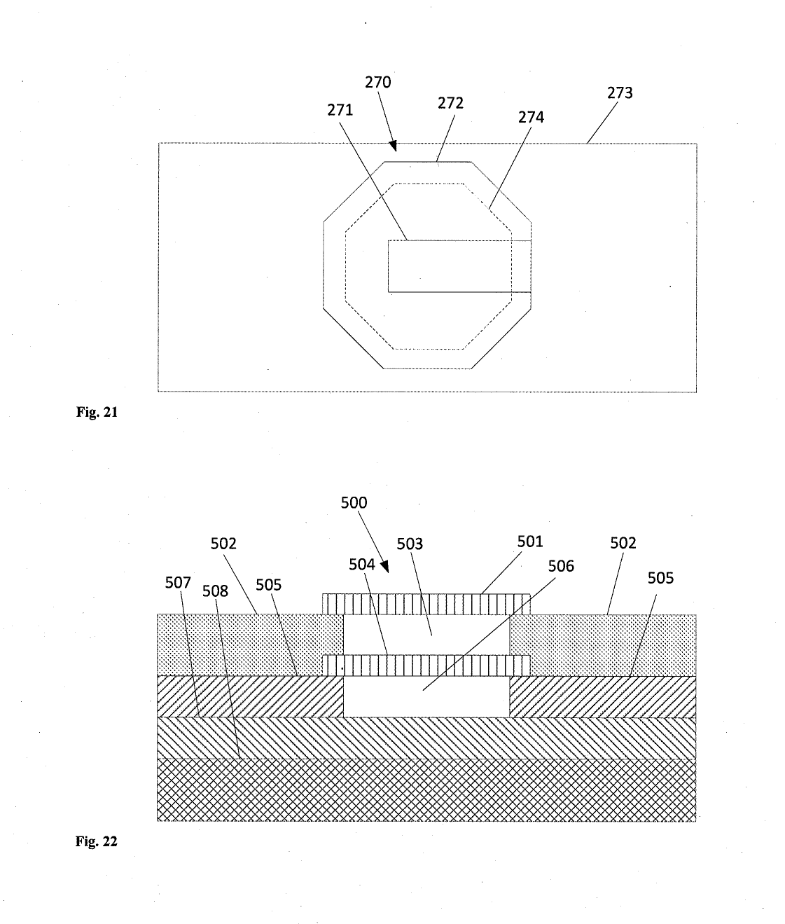

Referring to all vacuum gap devices of this document, the mechanical properties of the top conductor may be controlled by constructing the top conductor from multiple conductor layers. This is illustrated in FIG. 18 and FIG. 19 that show the top parts of the vacuum gap device 250. The sealing conductor 252 is reinforced by a supporting conductor 251 and they together form the top conductor. The sealing conductor 252 is on top of the vacuum gap 254 and insulator layer 253. The rest of the device details are omitted and shown here simply as layer 255. The shape of the supporting conductor 251 may be similar to the shape of the vacuum gap 254 but smaller in scale so that the center part of the top conductor will deform less than the edges. This may be useful for example when implementing capacitors, where the middle part of the top conductor will act as a capacitor top plate. Another variation of constructing the top conductor from two layers is shown in FIG. 20 where the sealing conductor 262, insulator layer 263 and vacuum gap 264 of the vacuum gap device 260 are similar to those of the vacuum gap device 250. The supporting conductor 261 is however shaped as a plus to increase the spring constant of the top conductor compared to the spring constant of the sealing conductor 262 only. Yet another variation of constructing the top conductor from two layers is shown in FIG. 21 where the sealing conductor 272, insulator layer 273 and vacuum gap 274 of the vacuum gap device 270 are similar to those of the vacuum gap device 250. The supporting conductor 271 is however shaped as a rectangle that can be thought to resemble a cantilever. If the sealing conductor 272 thickness is small compared to the supporting conductor 271 the mechanical behavior of the top conductor may be engineered to resemble cantilever behavior as opposed to a membrane if the top conductor thickness is constant.

In the above discussion of different top conductor from multiple conductor layers it is assumed that the conductor material is the same for all conductors; however it is possible to use different materials in order to for example make the device sensitive to temperature variations due to the different thermal expansion of the used materials. Also more than two layers may be used to construct the top conductor.

### General Remarks for all Described Vacuum Gap and Cantilever Devices

Referring to all the vacuum gap devices: The different conductor layers may use the same or different conductor materials; The conductor material may be a metal or a semiconductor or any other material that provides sufficient conductivity for the operation of the device; The insulator layers may use the same or different insulator materials; The conductors, even if referred to as being on top of an insulator, may be also completely or partially embedded in the top area of the insulator; In all mentioned devices the stationary conductor that is used to actuate the structure may consist of several separate actuation conductors each having a separate control voltage; The name double vacuum gap device may be used even though the two vacuum gaps are not physically separate, i.e. the middle conductor(s) are not covering the whole area between the vacuum gaps; When a vacuum gap is formed, there may be a conductive or insulating residual layer at the top and/or at the bottom of the vacuum gap, this is not shown in most device descriptions; In the contact forming devices the residual layer will be of a conductive material, whereas in devices where no contact is made between the conductors, the residual layer may be of conductive or insulating material; There may be no residual layer after the vacuum gap formation; The materials described in conjunction with the devices are simplifications, even though a single material is mentioned there could be several layers of different materials used instead to form e.g. an insulator; A tunneling device can be used in static mode or in mechanical resonance mode; There may be additional interconnection, passivation, device layers etc. on top of the vacuum gap devices; Any vacuum gap device can be used in quantum tunneling current mode even with larger gaps than 100 Å if the gap is temporarily reduced by e.g. applying contracting forces to the conductors or operating the device in resonance mode; The devices are intended to be connected electrically to other parts of the circuit although interconnections are not shown; None of the devices shown in figures are drawn to scale.

### Actuation and Sensing Mechanisms

The different actuation and sensing mechanisms of the vacuum gap and cantilever devices are not limited to electrostatic or pressure based forces, but also photonic interaction, thermal expansion, charge induction, acoustic waves, acceleration forces, Van der Waals forces and others may be used.

When used as a sensor the detection of the measured property in the resonating sensor may be based on changes in one or several of the natural mechanical resonance frequencies of the structure, amplitude of the resonance, changes in the tunneling current(s) of the device, nonlinearity of the device.

In a non-resonating structure the detection of the measured property may be based on the capacitance of the device, the tunneling current(s) of the device, the contact resistance of the device and electrical resonance frequency of an electrical resonator containing the device.

### 3-D Integration of Vacuum Gap Devices

Using conventional semiconductor processing such as the steps used for the interconnection generation of CMOS technology in addition to the process steps for making the vacuum gap devices, it is possible to integrate vacuum gap devices on many layers that are on top of each other. In CMOS technology, the processing of active devices such as p and n type transistors is limited to the surface layer of the substrate, effectively limiting the distribution of these components on a two dimensional plane within the chip. The vacuum gap devices do not have this limitation therefore it is possible to implement the vacuum gap devices on many separate layers thus allowing the integration in three dimensions. The ability of 3-D integration can greatly increase the device density on a single chip, which is especially beneficial in applications with high device counts such as digital logic and memory cells.

### Digital Logic

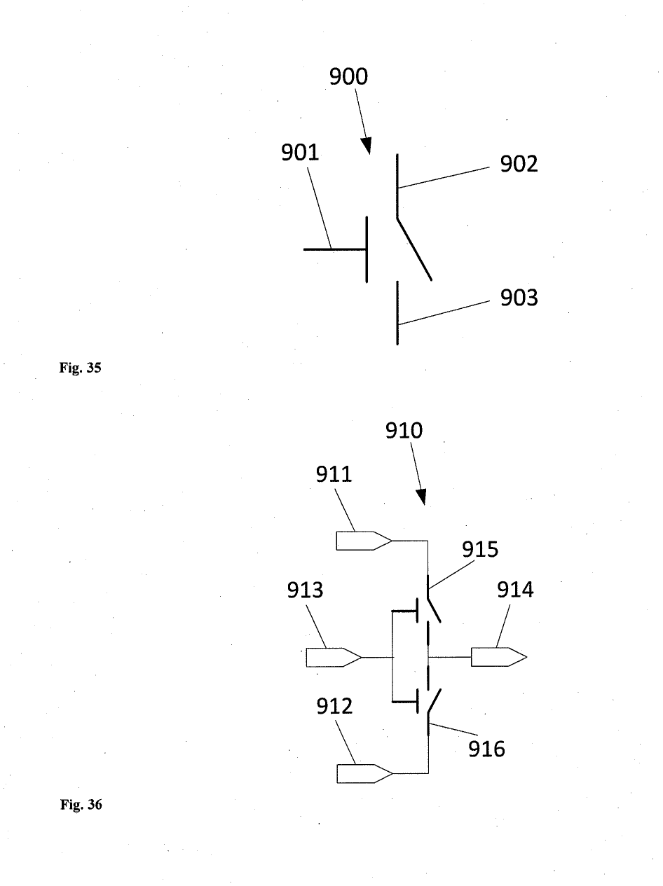

The described devices that can be used as a switch may be used as the basic building blocks to for a digital logic circuit. FIG. 35 shows a symbol of a switch 900. The switch 900 has a gate 901, drain 902 and source 903. The gate 901 is used to control the conductivity between the drain 902 and source 903 by applying a control voltage between the gate 901 and drain 902. A low control voltage will result in the switch 900 being in off state with low conductivity, ideally an open circuit between the drain 902 and the source 903, whereas a high control voltage will result in the switch 900 being in on state with a high conductivity, ideally a short circuit between the drain 902 and the source 903. The control voltage has a transition region between the low and high voltage where the conductivity of the switch 900 does not change, the range of this transition region may be different when the switch 900 is in on state as opposed to the off state. The switch 900 could be implemented for example from the single vacuum gap device 100 shown in FIG. 6 or the single gap cantilever device 800 shown in FIG. 29. The top conductor 101/801 acts as the drain 902, the actuation conductor 107/807 as the gate 901, and the contact conductor 104/contact conductor 807 as the source 903.

A digital inverter i.e. a logical NOT gate can be implemented by two mechanical switches 900. FIG. 36 shows an inverter 910 that is constructed of two mechanical switches 900 of FIG. 35. The positive operating voltage terminal 911 is connected to the drain of mechanical switch 915 and the negative operating voltage terminal 912 is connected to the drain of mechanical switch 916. The gates of mechanical switches 915 and 916 are connected to the inverter input 913. The sources of mechanical switches 915 and 916 are connected to the inverter output 914. As the inverter 910 is symmetric regarding the operating voltage terminals, the naming positive and negative is for reference only as the terminals are interchangeable.

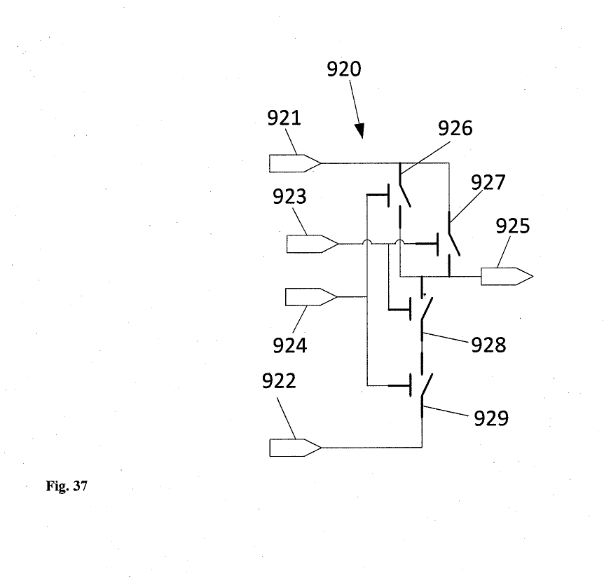

A logical NAND gate and logical NOR gate can be implemented by four mechanical switches 900. FIG. 37 shows a NAND gate 920 where the positive operating voltage terminal 921 is connected to the drains of mechanical switches 926 and 927. The negative operating voltage terminal 922 is connected to the drain of mechanical switch 929. The source of mechanical switch 929 is connected to the drain of mechanical switch 928. The sources of mechanical switches 926, 927 and 928 are connected to the NAND gate output 925. The NAND input A 923 is connected to the gates of mechanical switches 927 and 928. The NAND input B 924 is connected to the gates of mechanical switches 926 and 929.

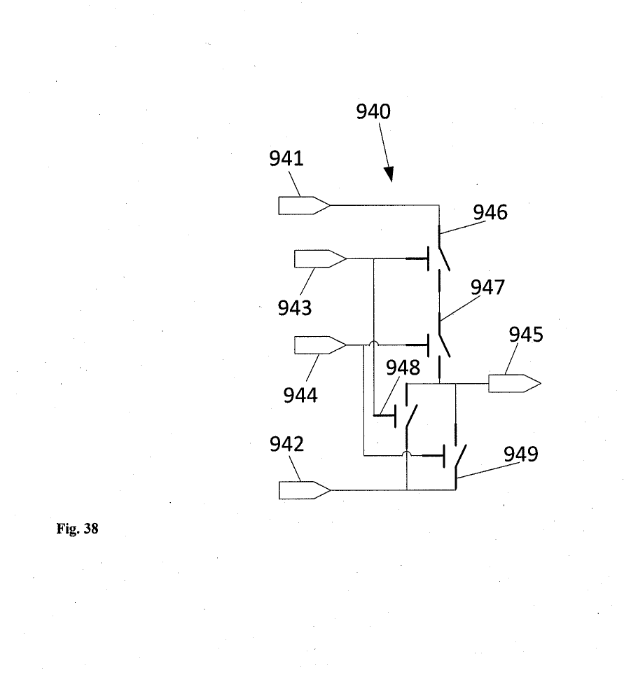

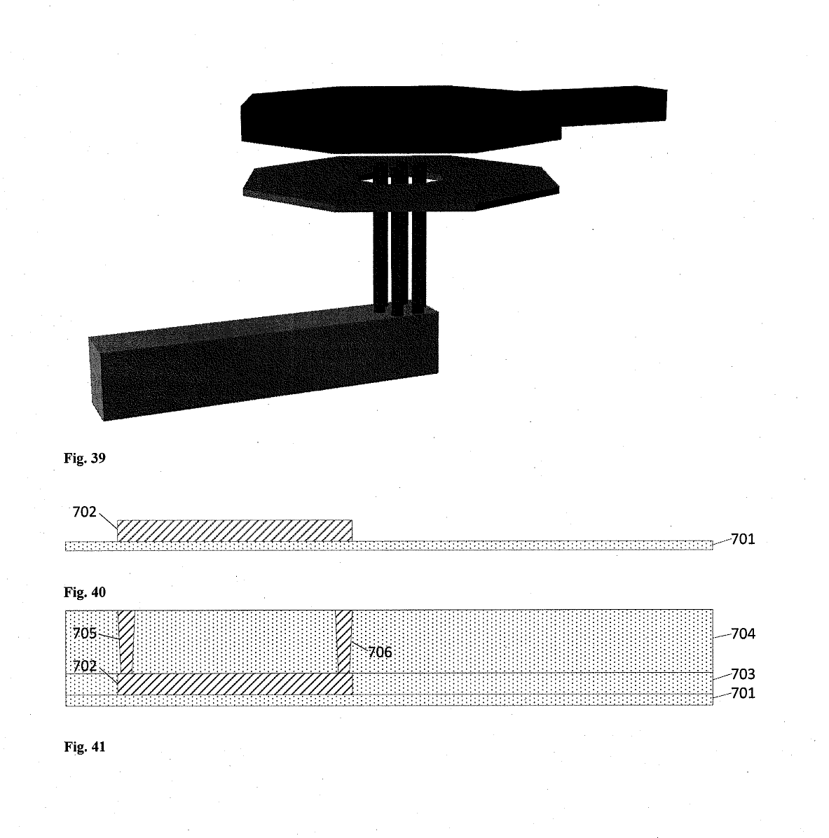

FIG. 38 shows a NOR gate 920 where the negative operating voltage terminal 942 is connected to the drains of mechanical switches 948 and 949. The positive operating voltage terminal 941 is connected to the drain of mechanical switch 946. The source of mechanical switch 946 is connected to the drain of mechanical switch 947. The sources of mechanical switches 947, 948 and 949 are connected to the NOR gate output 945. The NOR input A 943 is connected to the gates of mechanical switches 946 and 948. The NOR input B 944 is connected to the gates of mechanical switches 947 and 949. The NAND gate 920 can be configured into a NOR gate 940 by switching the polarity of the operating voltage terminals 921 and 922.

### Non-Contacting Switch

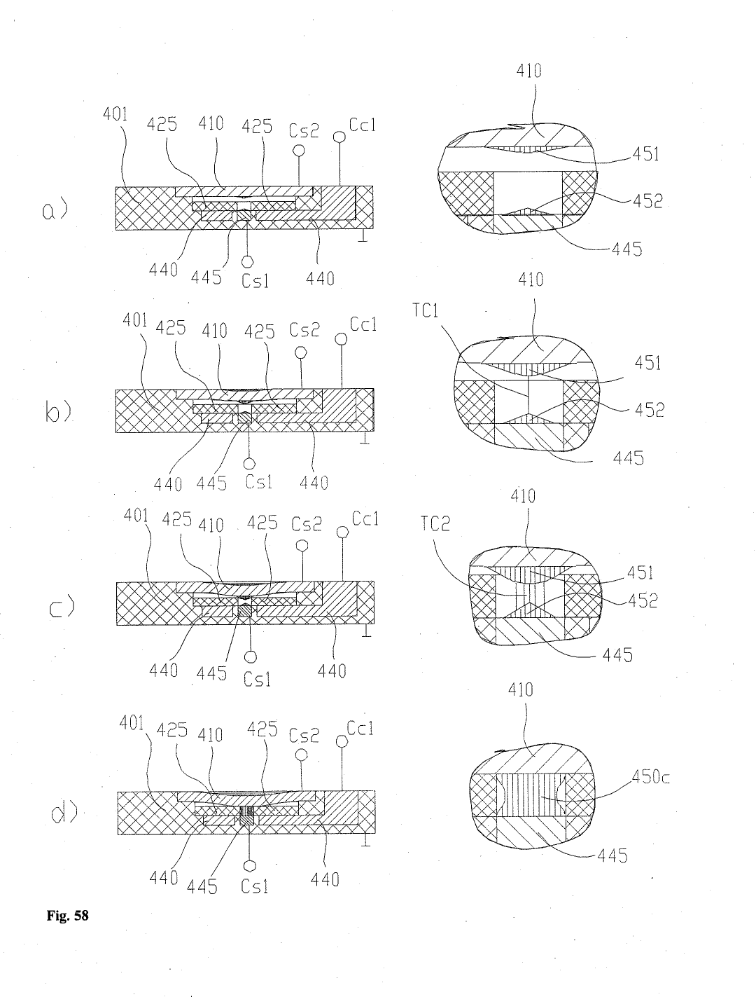

FIG. 58 shows a device in which an electrical contact with high conductivity is established without mechanical contact of two electrodes. The device comprises a resistive substrate 401, a control electrode 440, a central electrode 445 for switching, an insulator layer 425, a vacuum gap and a top electrode 410. The bottom electrode 440 and the top electrode 410 are separated by a thin insulator layer. The central electrode 445 and the top electrode 410 are separated by the vacuum gap only. In the middle, there is a hole in the insulator layer 425 providing vacuum space to the central electrode 445. When the electrostatic voltage is applied between the two electrodes 440 and 410, through connections Cs2 and Cc1, then the electrostatic force pulls the top electrode down. The vacuum gap separating the top electrode 410 and the central electrode 445, contact Cs1, becomes smaller. One can distinguish four stages in FIG. 58. Stage a) the vacuum gap separating the electrodes is relatively large providing electrical isolation. Electron clouds of the free electrons on the surfaces of each electrodes 451 and 452 are separated. Stage b) when the gap became slightly smaller enabling electrons to tunnel through the gap through one tunneling channel TC1. Electron clouds 451 and 452 of the free electrodes change their shapes and become closer to each other but are still separated. Stage c) when the gap is reduced to a value when a multichannel tunneling is possible. In this case, electrons can tunnel through multi-channels TC2 when a voltage is applied between the central and the top electrodes. Decreasing the gap size results in decreasing of barrier and tunneling probability increases. Electron clouds 451 and 452 are still separated. Stage d) when the two clouds of the free electrons overlap and form an Ohmic contact 450c of high conductivity between 445 and 410, connection Cs1 and Cs2. The top electrode 410 establishes the mechanical contact with the insulating layer 425 but is still separated mechanically from the central electrode 445. Because the electron clouds 451 and 452 are overlapped, then this region provides a high conductivity. We call this contact as electron cloud contact (ECC). When electrical voltage is applied between the central and top electrodes then electrons can freely travel through the ECC contact 450c. Conductivity of this contact is high and the ECC contact provides a good Ohmic contact. This effect can be used in switches, for example, in different designs.

### Method of Fabrication

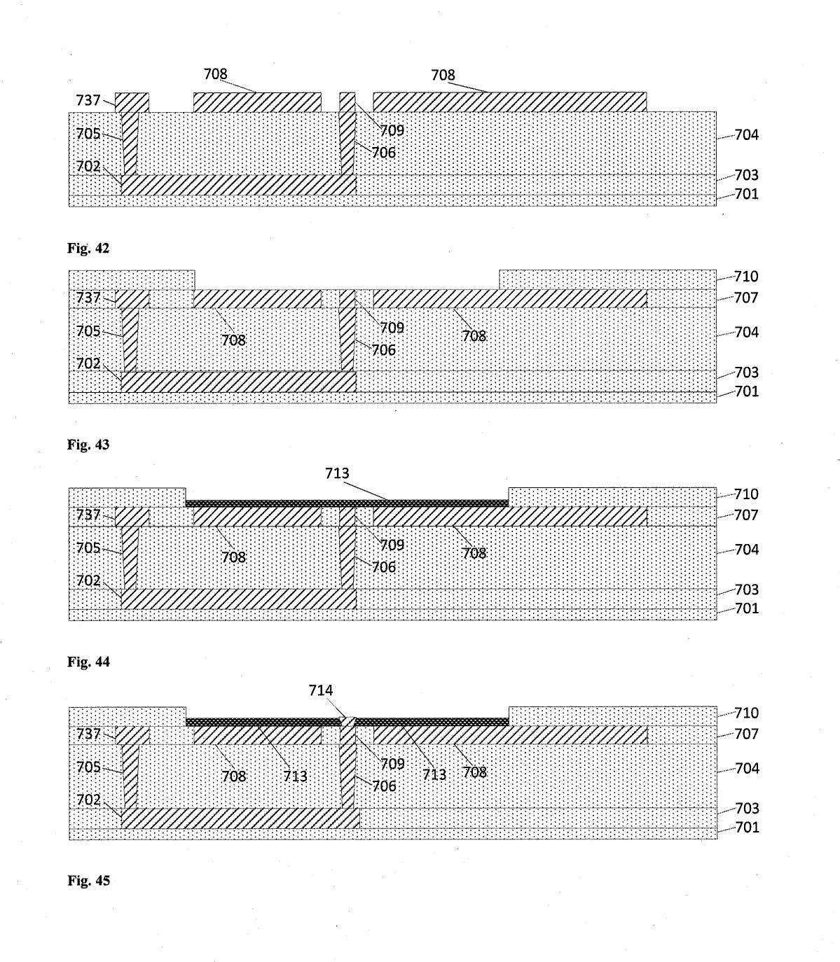

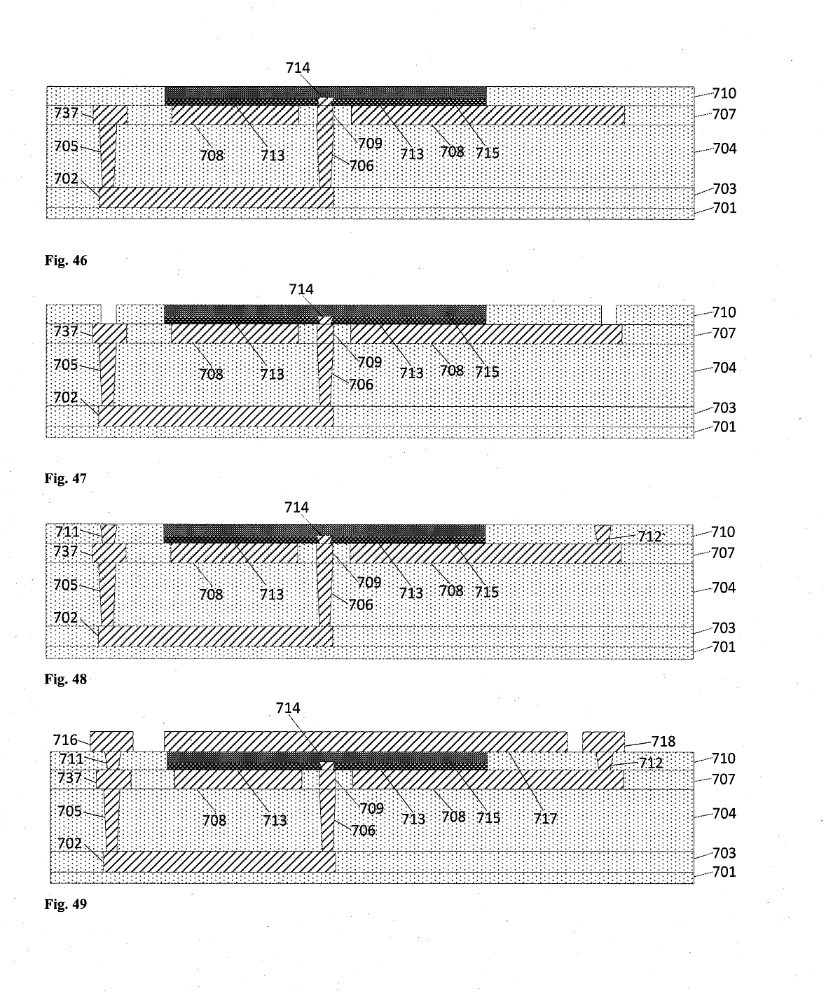

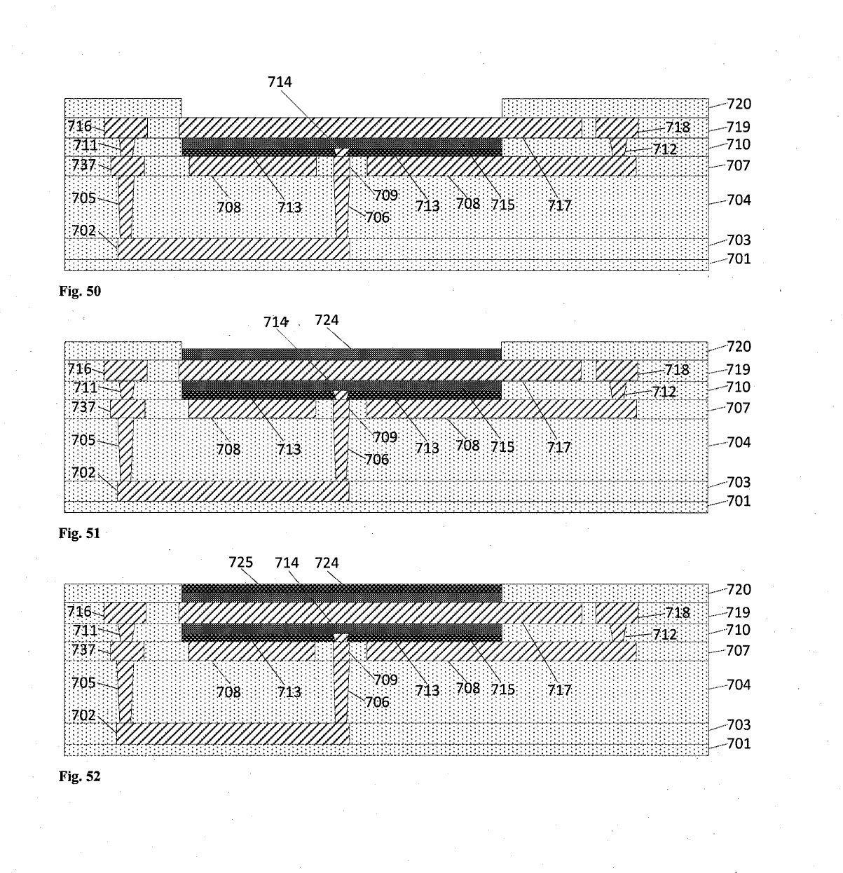

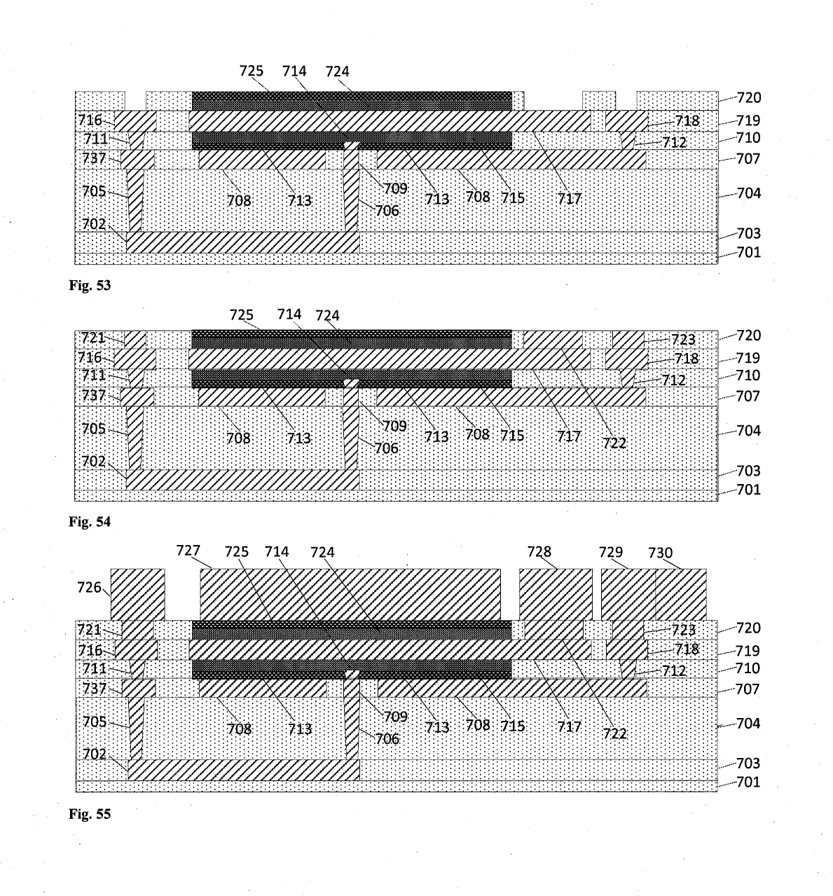

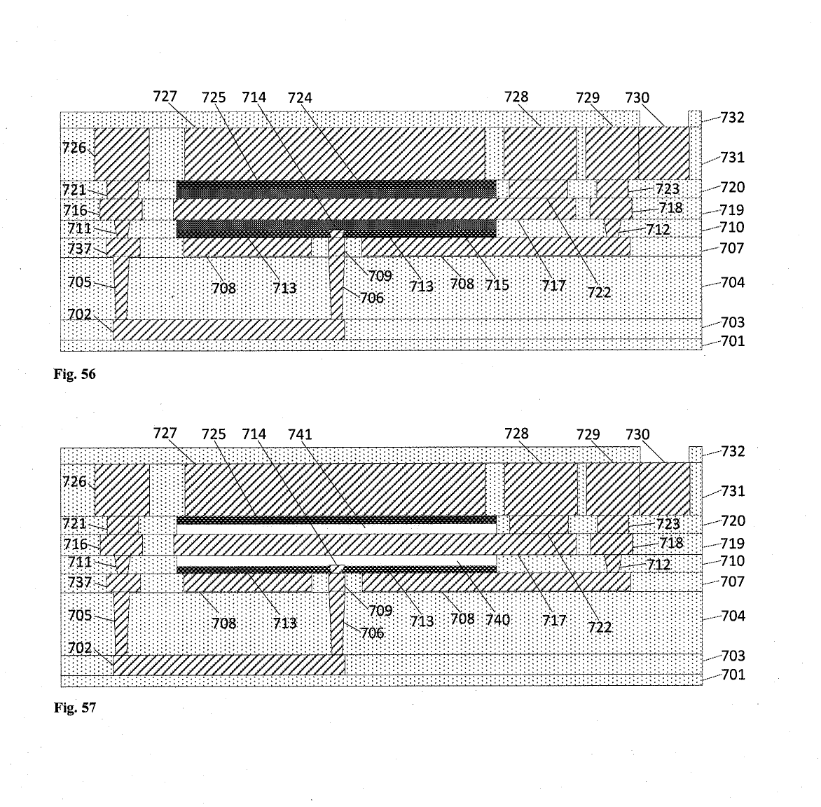

The designs disclosed in this invention can be realized by using a special procedure to produce vacuum gaps. FIGS. 40-57 show steps of fabrication of a dual gap device using a conventional CMOS process. The device is prepared by deposition of thin film layers. The layers are structured using lithography and etching and, finally, vacuum gas is formed by diffusion of density changing materials. Here we don't show all standard steps, but an experienced person can understand the fabrication steps shown in the figures. FIG. 40 shows initial fabrication steps. Fabrication starts from the carrier material 701 (insulator 1), on which one prepares the bottom interconnection 702 (metal 1) and the insulator layer 703 (insulator 2). The bottom interconnection 702 can be patterned by using a lithography followed by deposition of metal followed by deposition of the insulator material filling the reminder space of the insulator layer 703. In order to obtain equal thicknesses one can make the insulator layer 703 slightly thicker first followed by planarization, for example, by etching. The bottom interconnection 702 is used to provide electrical connection to the interconnection 709, metal 2 which is a part of contact conductor. Next step, comprises interconnection 705 (via 1) and interconnection 706 (via 1 which is a part of contact conductor) to provide electrical connection and reminder space is filled with the insulator layer 704 (insulator 3). Next step, is preparation of the interconnection 737 (metal 2) for providing electrical connection to the interconnection 709, metal 2 which is a part of contact conductor; actuation conductor 708 (metal 2) which consist of the actuation conductor and some interconnection. The actuation conductor 708 may have different geometries. One of simple geometries is a structure surrounding the interconnection 709. The space in-between the metal structures of this layer is filled with an insulator layer 707 (insulator 4) shown in FIG. 42. Next step is shown in FIG. 44 where insulator layer 710 (insulator 5) is prepared with an opening area above the actuation conductor 708 and interconnection 709. Next step shown in FIG. 45 is preparation of the top high k insulator layer 713 inside the opening area covering actuation conductor 708 and contact conductor 709. Next step shown in FIG. 46 is preparation of a hole (not shown separately) in the insulator layer 713 and filling the hole with the switch contact 714 which is a part of contact conductor, on top of the interconnection 709. Next step is shown in FIG. 46 where a density changing material (DCM) 715 is prepared on top of the top high k insulator layer 713 and switch contact 714. This DCM 715 is used to form a vacuum gap. Next step is shown in FIG. 47 where holes are made in the insulator layer 710 to be filled with interconnection 711 (via 2) and interconnection 712 (via 2) as shown in FIG. 48. The structures on insulator layer 710 are formed. Next step shown in FIG. 49 is preparation of interconnection 716, middle conductor 717 (moving membrane with an interconnection part) and interconnection 718 (all metal 3). Next step is preparation of an insulator layer 719 (insulator 6) on the same level with interconnection 716, middle conductor 717 and interconnection 718 followed by preparation of a new insulator layer 720 (insulator 7) with an opening over the middle conductor 717 as shown in FIG. 50. Next step shown in FIG. 51 is preparation of second density changing material DCM 724 on top of the middle conductor 717. Next step is preparation of the top high k insulator layer 725 on top of the DCM 724 as shown in FIG. 52. Next step is preparation of holes in the insulator layer 720 shown in FIG. 53 followed by filling the holes with interconnection 721, interconnection 722, and interconnection 723 (all via 3), for electrical connection as shown in FIG. 54. All structures on insulator layer 720 are formed. FIG. 55 shows preparation of interconnection 726 (metal 4); top conductor 727 (metal 4); interconnection 728 (metal 4); interconnection 729 (metal 4); and bonding pad 730 (metal 4). Next step is filling space between the metal structures with insulator material 731, shown in FIG. 55. The structures on insulator layer 731 are formed. A top insulator layer 732(passivation layer) is prepared on top of the device as shown in FIG. 56 followed by etching holes to provide access to the bonding pads through the openings. After all structures are prepared, a special condition(s) is (are) provided so that the density changing materials shrink releasing lower vacuum gap 740, and upper vacuum gap 741. Increasing of its density results in shrinking the volume releasing the vacuum gaps 740 and 741. FIG. 57 shows the final device.

The formation of the vacuum gap is based on the patented idea described in the following patent applications, which are hereby incorporated by reference in their entirety;
patent application U.S. Ser. No. 12/370,882 “Resonant MEMS device that detects photons, particles and small forces”, ScanNanoTek;
patent application U.S. Ser. No. 12/961,079 “Electromechanical systems, waveguides and methods of production”, ScanNanoTek.
U.S. patent application 61/388,481 “Method for fabrication of deep vacuum gap cavities inside materials”, ScanNanoTek.
U.S. Patent application 61/417,537 “Metal and semiconductor nanotubes and hollow wires and method for their fabrication”, ScanNanoTek.

The fabrication of the transition layer including vacuum gap is based on the use of a density changing material DCM. The material is prepared along with other structures of the devices. After the device is fabricated, the DCM shrinks in special conditions releasing the vacuum gap. Shrinking of the DCM layer is a result of increase of density. This can be calculated using number of atoms participating in diffusion process and chemical reaction. Particularly, as an example, the following metals and oxides, can compose the DCM and the MEMS device described above;

Cu and its oxide as a base material for DCM, alternative materials are Hf, Ta, Zr, alloy of SrTi
Insulator material SiO2
High k insulator can be, for example, CuO, Al2O3, oxides of Hf, Ta, Zr, SrTi
MEMS structure material Al—Si, or Ti, W, Mo. When the structure is made of Al—Si, then one can deposit a thin layer of AlN or Ti3N4 on top.
Oxide of Cu for the second DCM

The following materials can be used with Al:

### V, Nb, Cr, Mn, Fe, Co, Ti, Ni, Cu, Ag, Re, W, Mo, Ge, Si.

There are possible variations of the devices disclosed in this patent application as well as other designs based on use of one or more vacuum gaps with variations of insulator materials. Such variations are covered by this specification.

The parts are indicated as follows (in parentheses typical reference to CMOS BEOL layer name such as metal X, via Y and insulator Z, and additional remarks);
701 carrier material (insulator 1)
702 bottom interconnection (metal 1)
703 insulator layer (insulator 2)
704 insulator layer (insulator 3)
705 interconnection (via 1)
706 interconnection (via 1, part of contact conductor)
707 insulator layer (insulator 4)
708 actuation conductor (metal 2, including interconnection)
709 interconnection (metal 2, part of contact conductor)
710 insulator layer (insulator 5)
711 interconnection (via 2)
712 interconnection (via 2)
713 bottom high k insulator layer 714 switch contact (part of contact conductor)
715 bottom density changing material layer
716 interconnection (metal 3)
717 middle conductor (metal 3 moving membrane and interconnect)
718 interconnection (metal 3) 719 insulator layer (insulator 6)
720 insulator layer (insulator 7)
721 interconnection (via 3)
722 interconnection (via 3)
723 interconnection (via 3)
724 top density changing material layer
725 top high k insulator layer
726 interconnection (metal 4).
727 top conductor (metal 4)
728 interconnection (metal 4)
729 interconnection (metal 4)
730 bonding pad (metal 4)
731 insulator layer (insulator 8)
732 insulator layer (passivation layer, has opening for bonding pad)
737 interconnection (metal 2)
740 lower vacuum gap
741 upper vacuum gap

Layers 701, 703, 704, 707, 710, 719, 720, 731 and 732 are dielectric material layers that extend over the whole width of the chip, even if there are other materials or gaps shown at certain locations in the layer.

### Example of Variable Capacitor

FIG. 57 shows the final results of processing steps where the device is resembling the dual vacuum gap device (switch).

### Additional Application Areas

Possible applications of the invention: analog variable capacitor, digital variable capacitor, mechanical resonator, tunable electrical resonator, DC switch, RF switch, DC-to-DC converter, class D audio amplifier, tunable inductor, tunable matching network, phase shifter, SPST switch, SWDP switch, SPNT switch, switch matrix, vacuum tube, tunable filter, switched filter banks, MEMS filter, digital logic, programmable attenuator, acceleration sensor, photo detector, tunneling diode, thermionic diode, thermotunneling diode, pressure sensor, microphone, memory cell.

While the foregoing written description of the inventions enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

1. A MEMS switch, comprising:
a top conductor;
at least one first insulator layer having a lateral opening, wherein the at least one first insulator layer is hermetically sealed to the top conductor;
at least one second insulator layer positioned below the at least one first insulator layer such that at least one vacuum gap is formed within the lateral opening between the top conductor and the at least one second insulator layer, said at least one vacuum gap having a thickness in the range 0.5 Å to 100 Å when said top conductor is at rest, wherein the thickness of the at least one vacuum gap varies when the top conductor is moved;
at least one contact conductor, wherein said second insulator layer has at least one opening that exposes a conducting area of the at least one contact conductor within the second insulator layer; and
at least one actuation conductor electrically insulated from the at least one contact conductor, wherein application of at least one actuation voltage to the at least one actuation conductor moves the at least one contact conductor and the top conductor closer to each other within the at least one vacuum gap.

2. The switch of claim 1, wherein the at least one contact conductor is positioned within the at least one opening of said second insulator layer such that upon application of the actuation voltage a mechanical contact is created between the top conductor and the at least one contact conductor.

3. The switch of claim 1, wherein the at least one contact conductor is positioned within the at least one opening of said second insulator layer such that upon application of the actuation voltage to the at least one actuation conductor a high conduction path is created between the top conductor and the at least one contact conductor without forming a mechanical contact between them.

4. The switch of claim 1, further comprising a bottom interconnection in electrical contact with the contact conductor, said bottom interconnection being disposed below the at least one second insulation layer.

5. The switch of claim 1, wherein at least one of the first insulator layer or the at least one second insulator layer comprise at least one of silicon oxide, silicon nitride or low-k material (what is a low-k material? examples).

6. The switch of claim 1, further comprising at least one third insulator layer that insulates the bottom conductor from a carrier of MEMS device.

8. The switch of claim 3, wherein the carrier material comprises at least one of silicon, gallium arsenide, glass, quartz or sapphire.

9. The switch of claim 1, wherein the at least one top conductor comprises at least one of gold, tungsten, copper, aluminum or polysilicon.

10. The switch of claim 1, wherein the at least one contact conductor comprises a plurality of contact conductors, and wherein said second insulator layer has a plurality of openings each exposing a conducting area of a corresponding one of the plurality of the contact conductors to increase actuation area.

11. The switch of claim 1, wherein the at least one actuation conductor comprises a plurality of actuation conductors for applying different actuation voltages to each one of the plurality of actuation conductors.

12. The switch of claim 1, wherein the top conductor and the at least one actuation conductor are spaced to minimize parasitic capacitance.

13. The switch of claim 1, wherein the at least one contact conductor is positioned within the at least one opening of the at least one second insulator layer such that a high conduction path is creating between the top conductor and the at least one contact conductor without forming a mechanical contact there between.

14. The switch of claim 1, further comprising at least one middle conductor positioned between the top conductor and the at least one first insulator layer thereby forming a plurality of vacuum gaps, each one of the plurality of vacuum gaps having a thickness in the range 0.5 Å to 100 Å.
